(19) United States
(12) Patent Application Publication
(10) Pub. No.: US 2024/0324204 A1
(43) Pub. Date: Sep. 26, 2024

(54) SEMICONDUCTOR MEMORY DEVICE AND METHOD OF MANUFACTURING SEMICONDUCTOR MEMORY DEVICE

(71) Applicant: SK hynix Inc., Icheon-si Gyeonggi-do (KR)

(72) Inventor: In Ku KANG, Icheon-si Gyeonggi-do (KR)

(73) Assignee: SK hynix Inc., Icheon-si Gyeonggi-do (KR)

(21) Appl. No.: 18/464,838

(22) Filed: Sep. 11, 2023

(30) Foreign Application Priority Data
Mar. 22, 2023 (KR) 10-2023-0037445

(51) Int. Cl. H10B 43/27; H10B 41/27

(52) U.S. Cl. CPC H10B 43/27; H10B 41/27

(57) ABSTRACT

A semiconductor memory device Includes a gate stack, a first data storage segment and a second data storage segment. The gate stack includes a first and second concave portions, which face opposite directions. The first and second t data storage segments correspond to the first and second concave portions.

### CROSS-REFERENCE TO RELATED APPLICATION

The present application claims priority under 35 U.S.C. § 119(a) to Korean patent application number 10-2023-0037445 filed on Mar. 22, 2023, in the Korean Intellectual Property Office, the entire disclosure of which is incorporated by reference herein.

### BACKGROUND

### 1. Technical Field

The present disclosure relates to a semiconductor memory device and a method of manufacturing the semiconductor memory device.

### 2. Related Art

Semiconductor memory devices are used in a wide variety of electronic devices in a wide variety of various fields, including computers, communications equipment, automobiles, aviation, navigation, transportation, medicine, and medical care, to name just a few. The demand for semiconductor memory devices therefore continued to increase.

A semiconductor memory device may include a memory cell for data storage. In order to increase a capacity of the semiconductor memory device, a three-dimensional semiconductor memory device has been developed, which may include memory cells arranged in a three-dimensional structure.

### SUMMARY

According to an embodiment of the present disclosure, a semiconductor memory device may include a gate stack including a first concave portion and a second concave portion, the first and second concave portions facing opposite directions based on a straight line on a geometric plane, an insulating pillar having a first convex portion facing the first concave portion of the gate stack and a second convex portion facing the second concave portion of the gate stack, a first channel segment extending along the first convex portion of the insulating pillar, a second channel segment extending along the second convex portion of the insulating pillar, a channel separation structure extending from the insulating pillar to between an end of the first channel segment and an end of the second channel segment, a first data storage segment located between the first channel segment and the first concave portion of the gate stack, and a second data storage segment located between the second channel segment and the second concave portion of the gate stack. A width of each of the first data storage segment and the second data storage segment may become narrower as each of the first data storage segment and the second data storage segment is close the channel separation structure.

According to an embodiment of the present disclosure, a semiconductor memory device may include an insulating pillar having a first convex portion and a second convex portion, the first and second convex portions facing opposite directions based on a straight line on a geometric plane, a gate separation structure located alternately with the insulating pillar in a direction, in which the straight line extends, a first sub-stack including a first concave portion facing the first convex portion of the insulating pillar and further including a plurality of first conductive layers spaced apart from each other and stacked in a direction, which is orthogonal to the straight line, a second sub-stack including a second concave portion facing the second convex portion of the insulating pillar and including a plurality of second conductive layers spaced apart from each other and stacked in the direction, which is orthogonal to the straight line, a first data storage segment located between the first convex portion of the insulating pillar and the first concave portion of the first sub-stack, a second data storage segment located between the second convex portion of the insulating pillar and the second concave portion of the second sub-stack, and a channel layer located between the first data storage segment and the first convex portion of the insulating pillar and between the second data storage segment and the second convex portion of the insulating pillar. A width of each of the first data storage segment and the second data storage segment may become narrower as each of the first data storage segment and the second data storage segment is close to the gate separation structure.

According to an embodiment of the present disclosure, a method of manufacturing a semiconductor memory device may include forming a preliminary stack including a plurality of first material layers and a plurality of second material layers, the first and second material layers being alternately stacked, forming a hole passing through the preliminary stack, forming a data storage layer inside the hole, the data storage layer including an inner portion defining a first elliptical opening having a minor axis facing a first direction on a geometric plane and a major axis facing a second direction crossing the minor axis and an outer portion facing the preliminary stack, isotropically etching the data storage layer through the first elliptical opening so that the first elliptical opening extends to a second elliptical opening having a major axis facing the first direction and a minor axis facing the second direction, and forming a channel layer inside the second elliptical opening.

According to an embodiment of the present disclosure, a method of manufacturing a semiconductor memory device may include forming a preliminary stack including a plurality of first material layers and a plurality of second material layers, the first and second material layers being alternately stacked, forming a gate separation structure passing through the preliminary stack and extending in a first direction, forming a hole passing through the gate separation structure and extending into the preliminary stack on both sides of the gate separation structure, forming a data storage layer inside the hole, the data storage layer including an inner portion defining a first elliptical opening having a minor axis facing the first direction and a major axis facing a second direction crossing the minor axis and an outer portion facing the preliminary stack, isotropically etching the data storage layer through the first elliptical opening so that the first elliptical opening extends to a second elliptical opening having a major axis facing the first direction and a minor axis facing the second direction, and forming a channel layer inside the second elliptical opening.

### BRIEF DESCRIPTION OF THE DRAWINGS

FIG. 1 is a block diagram illustrating a semiconductor memory device according to an embodiment of the present disclosure.

FIG. 2 is a circuit diagram of a memory cell string according to an embodiment of the present disclosure.

FIGS. 3A and 3B are diagrams illustrating semiconductor memory devices according to embodiments of the present disclosure.

FIGS. 4A and 4B are cross-sectional views of semiconductor memory devices according to embodiments of the present disclosure.

FIGS. 5, 6A, 6B, 6C, 7A, and 7B are diagrams illustrating a semiconductor memory device according to an embodiment of the present disclosure.

FIGS. 8, 9A, and 9B are diagrams illustrating a semiconductor memory device according to an embodiment of the present disclosure.

FIGS. 10A and 10B are diagrams illustrating semiconductor memory devices according to embodiments of the present disclosure.

FIGS. 11, 12A, and 12B are diagrams illustrating a semiconductor memory device shown in FIG. 10A or 10B.

FIGS. 13, 14A, and 14B are diagrams illustrating a semiconductor memory device according to an embodiment of the present disclosure.

FIGS. 15, 16A, and 16B are diagrams illustrating a semiconductor memory device according to an embodiment of the present disclosure.

FIGS. 17, 18, 19A, and 19B are diagrams illustrating a semiconductor memory device according to an embodiment of the present disclosure.

FIGS. 20, 21A, 21B, 22A, 22B, 23A, 23B, 24A, 24B, 25A, 25B, 26, 27A, 27B, 28A, 28B, 29A, 29B, 30A, and 30B are diagrams illustrating a method of manufacturing a semiconductor memory device according to an embodiment of the present disclosure.

FIGS. 31A and 31B are plan views illustrating a method of manufacturing a semiconductor memory device according to an embodiment of the present disclosure.

FIGS. 32A and 32B are plan views illustrating a method of manufacturing a semiconductor memory device according to an embodiment of the present disclosure.

FIGS. 33, 34A, 34B, 35, and 36 are diagrams illustrating a method of manufacturing a semiconductor memory device according to an embodiment of the present disclosure.

FIG. 37 is a plan view illustrating a method of manufacturing a semiconductor memory device according to an embodiment of the present disclosure.

FIGS. 38, 39A, 39B, 40, 41A, 41B, and 42 are diagrams illustrating a method of manufacturing a semiconductor memory device according to an embodiment of the present disclosure.

FIGS. 43A, 43B, and 43C are plan views illustrating a method of manufacturing a semiconductor memory device according to an embodiment of the present disclosure.

FIG. 44 is a plan view illustrating a method of manufacturing a semiconductor memory device according to an embodiment of the present disclosure.

FIG. 45 is a block diagram illustrating an electronic system including a semiconductor memory device according to embodiments of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

Embodiments of the present disclosure may provide a semiconductor memory device and a method of manufacturing the semiconductor memory device capable of increasing an integration degree of a memory cell.

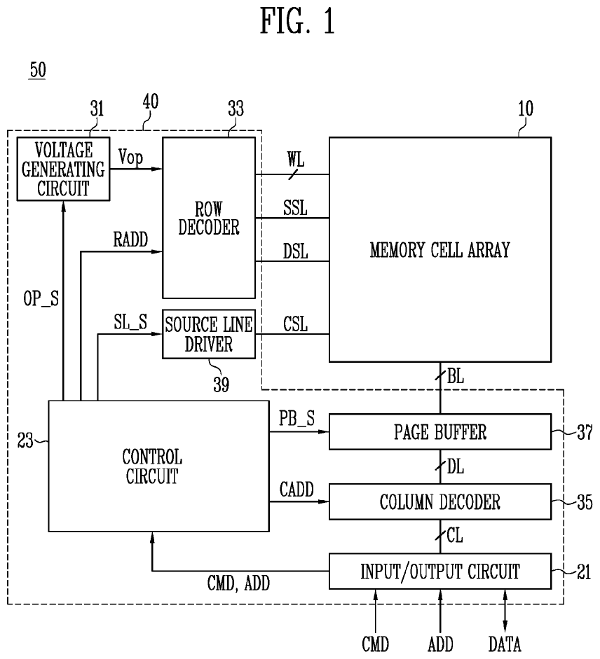

FIG. 1 is a block diagram illustrating a semiconductor memory device 50 according to an embodiment of the present disclosure.

The semiconductor memory device 50 may include a peripheral circuit 40 and a memory cell array 10.

The peripheral circuit 40 may be configured to perform a program operation for storing data in the memory cell array 10, a read operation for outputting data stored in the memory cell array 10, and an erase operation for erasing data stored in the memory cell array 10. In one embodiment, the peripheral circuit 40 may include an input/output circuit 21, a control circuit 23, a voltage generating circuit 31, a row decoder 33, a column decoder 35, a page buffer 37, and a source line driver 39.

The peripheral circuit 40 may be connected to the memory cell array 10 through a common source line CSL, a bit line BL, a drain select line DSL, a word line WL, and a source select line SSL.

The input/output circuit 21 may transmit to the control circuit 23, a command CMD and an address ADD received from an external device (for example, a memory controller) of the semiconductor memory device 50. The input/output circuit 21 may also exchange data DATA between the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operation voltages Vop, in response to the operation signal OP_S. The operation voltages Vop may be used for a program operation, a read operation, and an erase operation.

The row decoder 33 may transmit the operation voltages Vop, to the drain select line DSL, the word line WL, and the source select line SSL in response to a row address RADD.

The column decoder 35 may transmit the data DATA input from the input/output circuit 21 to the page buffer 37 or transmit the data DATA stored in the page buffer 37 to the input/output circuit 21, in response to a column address CADD. The column decoder 35 may exchange the data DATA with the input/output circuit 21 through a column line CL. The column decoder 35 may exchange the data DATA with the page buffer 37 through a data line DL.

The page buffer 37 may store read data received on or through the bit line BL, in response to the page buffer control signal PB_S. The page buffer 37 may also sense a voltage or a current of the bit line BL during a read operation.

The source line driver 39 may control a voltage applied to the common source line CSL in response to the source line control signal SL_S.

The memory cell array 10 may include a plurality of memory blocks. Each memory block may include a plurality of memory cells arranged in three dimensions. The memory cells may be divided into a plurality of memory cell strings. Each memory cell may be a nonvolatile memory cell. In one embodiment, the memory cells may be comprised of NAND flash memory cells.

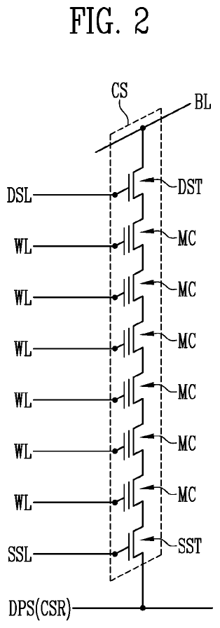

FIG. 2 is a circuit diagram of a memory cell string CS, according to an embodiment of the present disclosure.

The memory cell string CS may include at least one source select transistor SST, a plurality of memory cells MC, and at least one drain select transistor DST. The memory cells MC may be connected in series between the source select transistor SST and the drain select transistor DST. The source select transistor SST, the plurality of memory cells MC, and the drain select transistor DST may be connected in series by a channel pillar, not shown in FIG. 2. The channel pillar may be used as a channel region of the memory cell string CS and may be formed of a semiconductor layer.

A common source region CSR and the bit line BL may be connected to the channel pillar of the memory cell string CS. A voltage for discharging a potential of the channel region of the memory cell string CS may be applied to the common source region CSR. A voltage for precharging the channel region of the memory cell string CS may be applied to the bit line BL.

The plurality of memory cells MC of the memory cell string CS may be connected to the common source region CSR via the source select transistor SST. The plurality of memory cells MC of the memory cell string CS may be connected to the bit line BL via the drain select transistor DST.

Gate electrodes of the source select transistor SST, the memory cells MC, and the drain select transistor DST may form a gate stack. The gate stack may also include the source select line SSL, which is connected to, or extends from the gate electrode of the source select transistor SST, a plurality of word lines WL, each of which is connected to a corresponding gate electrode of a memory cell MC, and the drain select line DSL, which is connected to the gate electrode of the drain select transistor DST.

The common source region CSR may be electrically connected to the common source line CSL shown in FIG. 1. The common source region CSR may be formed in a doped semiconductor structure DPS.

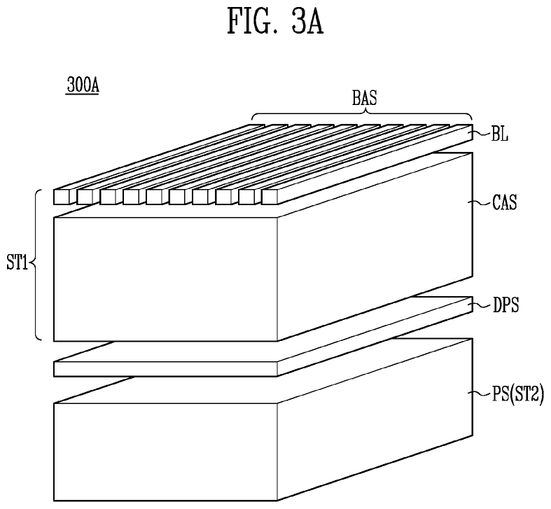

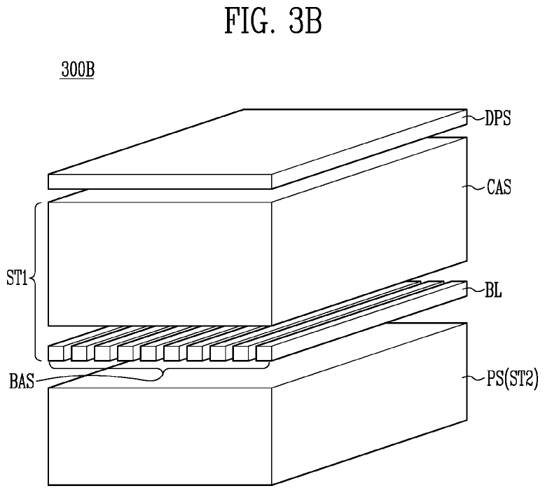

FIGS. 3A and 3B are diagram illustrating semiconductor memory devices 300A and 300B according to embodiments of the present disclosure.

The structures depicted in FIGS. 3A and 3B are not drawn to scale.

The semiconductor memory device 300A in FIG. 3A and the semiconductor device 300B depicted in FIG. 3B may each include a first structure ST1, a second structure ST2, and a doped semiconductor structure DPS. The first structure ST1 may include a cell array structure CAS and a bit line array structure BAS. The second structure ST2 may include a peripheral circuit structure PS.

The bit line array structure BAS may include the bit lines BL described with reference to FIGS. 1 and 2.

The cell array structure CAS may be located between the bit line array structure BAS and the doped semiconductor structure DPS. The cell array structure CAS may be included in the memory cell array 10 shown in FIG. 1 and may include the memory cell string CS shown in FIG. 2.

The doped semiconductor structure DPS may include an n-type impurity or a p-type impurity. The doped semiconductor structure DPS may include an n-type impurity and a p-type impurity. In one embodiment, the doped semiconductor structure DPS may include an n-type impurity region, which provides the common source region CSR shown in FIG. 2. In an alternate embodiment, the doped semiconductor structure DPS may include a p-type impurity region, which provides a well region.

The peripheral circuit structure PS may include a region overlapping the doped semiconductor structure DPS, the cell array structure CAS, and the bit line array structure BAS. The peripheral circuit structure PS may include a plurality of transistors, a capacitor, a resistor, and the like configuring the peripheral circuit 40 shown in FIG. 1.

The peripheral circuit structure PS may be adjacent to the doped semiconductor structure DPS as shown in FIG. 3A. In an alternate embodiment depicted in FIG. 3B, the doped semiconductor structure DPS may be adjacent to the bit line array structure BAS.

Although they are not shown in FIG. 3A or 3B, structures shown in FIGS. 3A and 3B may each have electrically conductive: interconnections, contacts, and conductive bonding pads, in order to provide electrical connections and electrical signal pathways inside and outside the memory device 300A, 300B, as well as into and out of the memory device 300A and 300B.

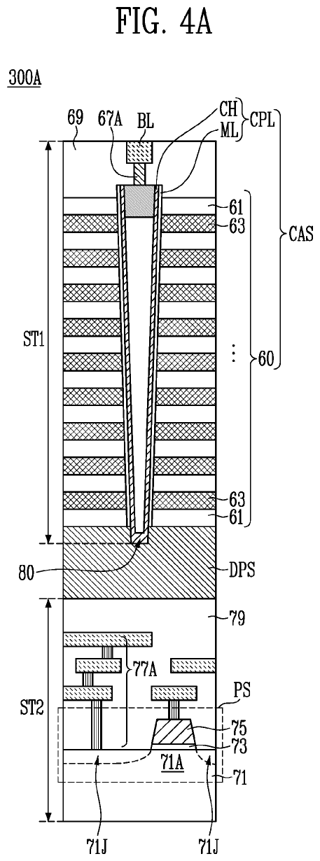

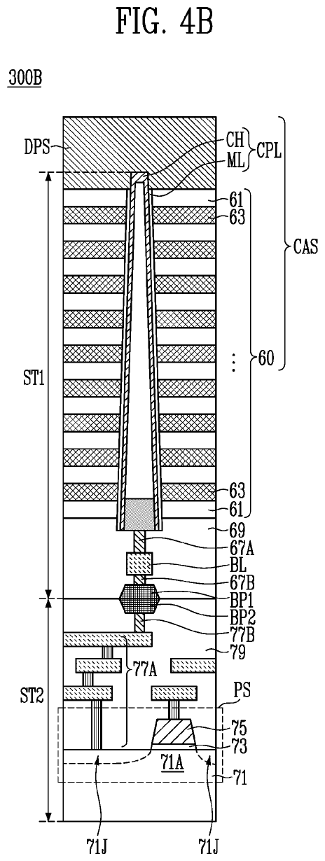

FIGS. 4A and 4B are cross-sectional views of semiconductor memory devices 300A and 300B according to embodiments of the present disclosure.

Referring to FIGS. 4A and 4B, each of the semiconductor memory devices 300A and 300B may include a first and second structures ST1 and ST2, as described with reference to FIGS. 3A and 3B. The first structure ST1 may include the cell array structure CAS and the bit line BL described with reference to FIGS. 3A and 3B. The cell array structure CAS may include a gate stack 60 located between the doped semiconductor structure DPS and the bit line BL, and a cell plug CPL passing through the gate stack 60.

The gate stack 60 may include a plurality of insulating layers 61 and a plurality of conductive layers 63 alternately stacked vertically, i.e., in a direction in which the horizontal surface of the doped semiconductor structure DPS “faces” the bit line BL. Individual conductive layers 63 may correspond to a source select line SSL, a drain select line DSL, and word lines WL, shown in FIG. 2.

The cell plug CPL may include a channel pillar CH, surrounded by a memory layer ML located between the channel pillar CH and alternately-stacked layers forming the gate stack 60. The channel pillar CH may be the channel region of the memory cell string CS shown in FIG. 2. Some regions of the memory layer ML may be used as data storage regions of the plurality of memory cells MC shown in FIG. 2.

The first structure ST1 may include a first insulating structure 69, which covers the gate stack 60. In one embodiment, the first insulating structure 69 may include multiple insulating layers. The bit line BL may be embedded into or “buried” in the first insulating structure 69. The bit line BL may be connected to the channel pillar CH of the cell plug CPL via a conductive bit line contact via or post 67A inside the first insulating structure 69.

The channel pillar CH may include bottom end 80, which is connected to the doped semiconductor structure DPS. The present disclosure is not limited thereto. Although not shown in the drawing, the doped semiconductor structure DPS may be connected to a portion of a sidewall of the channel pillar CH.

The second structure ST2 may include a semiconductor substrate 71, the peripheral circuit structure PS, a second insulating structure 79, and a plurality of interconnections 77A. The peripheral circuit structure PS may correspond to the peripheral circuit structure described with reference to FIGS. 3A and 3B.

The semiconductor substrate 71 may include an active region 71A partitioned by an element isolation layer (not shown). The peripheral circuit structure PS may include a transistor. A gate insulating layer 73 and a gate electrode 75 of the transistor may be stacked on the active region 71A of the semiconductor substrate 71. Source/drain junctions 71J of the transistor may be formed in the active region 71A on both sides of the gate electrode 75. The plurality of interconnections 77A may include sub-interconnections individually connected to the gate electrode 75 and the source/drain junction regions 71J.

The semiconductor substrate 71 and the peripheral circuit structure PS may be covered with the second insulating structure 79, and the plurality of interconnections 77A may be located inside the second insulating structure 79.

Referring to FIG. 4A, a process or processes of forming the doped semiconductor structure DPS and a process or processes of forming the first structure ST1 may be performed on top of the second structure ST2. As an embodiment, after forming the doped semiconductor structure DPS on the second structure ST2, a process of forming the first structure ST1 may be performed on top of the doped semiconductor structure DPS.

Referring to FIG. 4B, the formation process of the first structure ST1 and the formation process of the second structure ST2 may be individually performed. The first structure ST1 may include a first contact 67B and a first conductive bonding pad BP1 located in the first insulating structure 69. The second structure ST2 may include a second contact 77B and a second conductive bonding pad BP2 located in the second insulating structure 79. The first conductive bonding pad BP1 of the first structure ST1 and the second conductive bonding pad BP2 of the second structure ST2 provided through individual processes may be connected to each other through a bonding process. The doped semiconductor structure DPS may be provided after the bonding process.

The first conductive bonding pad BP1 may be electrically connected to the bit line BL or one of the conductive layers 63. The bit line BL may be electrically connected to the memory cell string via the first contact 67B. The conductive layers 63 may be electrically connected to the memory cell string. The second conductive bonding pad BP2 may be electrically connected to any one of elements configuring the peripheral circuit structure PS via the second contact 77B. As an embodiment, as shown in FIG. 4B, the first contact 67B, the first conductive bonding pad BP1, the second conductive bonding pad BP2, and the second contact 77B may be used for electrical connection between the bit line BL and a transistor configuring the page buffer 37 shown in FIG. 1. In this case, the bit line BL and the first conductive bonding pad BP1 may be electrically connected to each other by the first contact 67B, and one sub-interconnection among the plurality of interconnections 77A and the second conductive bonding pad BP2 may be electrically connected to each other by the second contact 77B.

The gate stack 60 and the cell plug CPL described above may be formed in various structures to improve the integration degree of the memory cells.

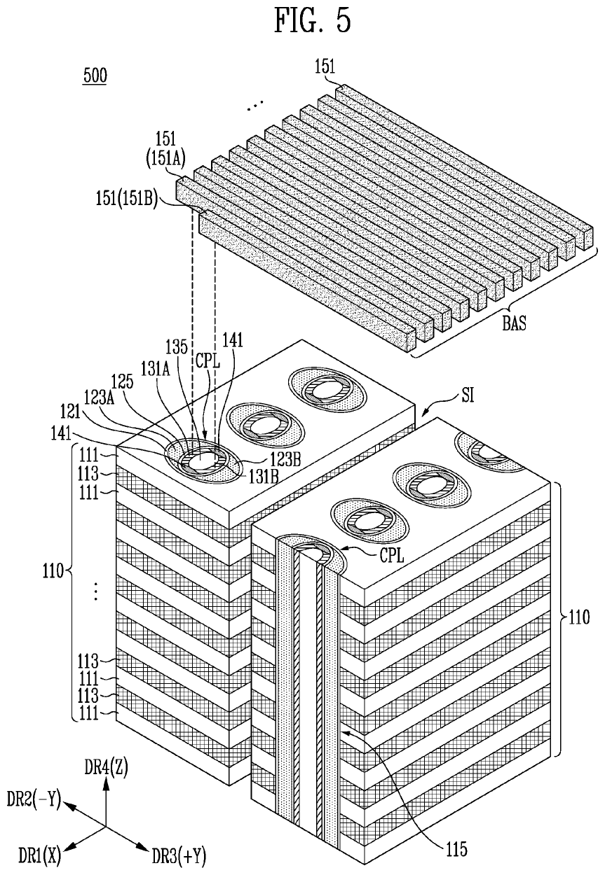

FIGS. 5, 6A, 6B, 6C, 7A, and 7B are diagrams illustrating a semiconductor memory device according to an embodiment of the present disclosure.

FIG. 5 is an exploded perspective view illustrating gate stacks of a semiconductor memory device 500. Referring to FIG. 5, the gate stacks of the semiconductor memory device 500 may include a first and second gate stacks 110, which are adjacent to, but laterally separated from each other by a space or slit SI. Cell plugs CPL may pass through each gate stack 110. A bit line array structure BAS may be formed on top of and extending over both the first and second gate stacks 110.

Each gate stack 110 may include a plurality of conductive layers 113 and a plurality of insulating layers 111, the layers 111, 113 being stacked vertically in the Z-axis direction. Two, vertically “adjacent” conductive layers 113 may be spaced apart from each other by an insulating layer 111 between them. Similarly, two vertically “adjacent” insulating layers 111 may be spaced apart from each other by a conductive layer 113 between them. Each layer 111, 113 is substantially planar. The layers 111, 113 may thus be considered to be plate-shaped and lying in the X-Y geometric plane, which is orthogonal to the Z-axis.

Each conductive layers 113 may be used as a word line WL shown in FIG. 2. Each conductive layer 113 may thus include at least one conductive material, examples of which include a doped semiconductor layer, a metal layer, and a conductive metal nitride layer. A doped semiconductor layer may include a doped silicon layer. A metal layer may include tungsten, copper, molybdenum, or the like. A conductive metal nitride layer may include titanium nitride, tantalum nitride, and the like. The insulating layer 111 formed between conductive layers 113 may include a silicon oxide layer or other equally-insulative material.

The cell plug CPL may be located inside a hole 115 formed in the gate stack 110. The hole 115 may extend in the Z-axis direction and thus pass through the conductive layers 113 and insulating layers 111 of the gate stack 110. The hole 115 may be formed such that its horizontal cross-sectional shape is elliptical, the ellipse having a minor axis in the first direction DR1 and a major axis in the second direction DR2.

As used herein the words “crescent” and “crescent-shaped” refer to a two or three-dimensional figure, which has both convex and concave edges, usually connected to each other at their respective ends.

The cell plug CPL may include a blocking insulating layer 121, a first data storage segment 123A, a second data storage segment 123B, a tunnel insulating layer 125, a first channel segment 131A, a second channel segment 131B, an insulating pillar 135, and two channel separation structures 141.

The first data storage segment 123A, a first blocking portion of the blocking insulating layer 121, which is adjacent to the first data storage segment 123A, and a first tunneling portion of the tunnel insulating layer 125 adjacent to the first data storage segment 123A may be considered as being a first region of the memory layer. Similarly, the second data storage segment 123B, a second blocking portion of the blocking insulating layer 121, which is adjacent to the second data storage segment 123B, and a second tunneling portion of the tunnel insulating layer 125 adjacent to the second data storage segment 123B may be considered as being a second region of the memory layer.

The blocking insulating layer 121 may include an insulating material capable of blocking a charge. The tunnel insulating layer 125 may include an insulating material capable of charge tunneling. The blocking insulating layer 121 may include an insulating layer having a dielectric constant higher than that of the tunnel insulating layer 125. Each of the first data storage segment 123A and the second data storage segment 123B may be formed of a material layer capable of storing changed data using Fowler Nordheim tunneling. As an embodiment, each of the first data storage segment 123A and the second data storage segment 123B may be formed of a charge trap insulating layer or an insulating layer including a conductive nano dot. The charge trap insulating layer may include a silicon nitride layer. The present disclosure is not limited thereto, and each of the first data storage segment 123A and the second data storage segment 123B may be formed of a material layer capable of storing information based on an operation principle other than Fowler Nordheim tunneling. In one embodiment, each of the first data storage segment 123A and the second data storage segment 123B may include a phase change material layer, a ferroelectric layer, or the like.

As used herein, “convex” refers to a shape that is curved or rounded outward. “Concave” on the other hand refers to a shape that is rounded inwardly.

As shown in FIG. 5, the first and second data storage segments 123A and 123B are “bounded” by the elliptically-shaped blocking insulating layer 121 and the smaller, the elliptically-shaped tunnel insulating layer 125. The major and minor axes of both those elliptically-shaped structures are collinear but have different lengths.

The first data storage segment 123A may thus be formed as a structure that is convex, i.e., rounded outwardly, in the second direction DR2. The second data storage segment 123B may be formed as a structure that is convex, i.e., rounded outwardly, in the third direction DR3, which is opposite to the second direction DR2. A width of each of the first data storage segment 123A and the second data storage segment 123B may become narrower toward an end of each of the first data storage segment 123A and the second data storage segment 123B. As an embodiment, a cross section of each of the first data storage segment 123A and the second data storage segment 123B may have a crescent shape.

Each of the first channel segment 131A and the second channel segment 131B may form a channel pillar of a memory cell string corresponding thereto. Each of the first channel segment 131A and the second channel segment 131B may be formed of a semiconductor material. In one embodiment, each of the first channel segment 131A and the second channel segment 131B may include silicon (Si), germanium (Ge), or a mixture thereof.

The bit line array structure BAS, which lies in a geometric X-Y plane (i.e., not in or on a physical surface or plane), may include a plurality of bit lines 151. Each bit line 151 may include a region overlapping, i.e., crossing over, the slit SI and with portions or sections of the bit lines 151, that extend in the second direction DR2 and the third direction DR3. The plurality of bit lines 151 may include a first bit line 151A connected to the first channel segment 131A and a second bit line 151B connected to the second channel segment 131B. The first channel segment 131A and the second channel segment 131B controlled by the same conductive layer 113 may be individually controlled through the first bit line 151A and the second bit line 151B.

Although it is not shown in FIG. 5, a first doped capping segment may be connected to an end of the first channel segment 131A proximate to and facing the bit line array structure BAS, and a second doped capping segment may be connected to an end of the second channel segment 131B proximate to and facing the bit line array structure BAS. Each of the first and second doped capping segments may be formed of a semiconductor layer including at least one of an n-type impurity and a p-type impurity. As an embodiment, each of the first and second doped capping segments may include an n-type impurity as a majority carrier. The first channel segment 131A may be connected to the first bit line BL1 via the first doped capping segment and the bit line contact described with reference to FIGS. 4A and 4B. The present disclosure is not limited thereto, and at least one of the first doped capping segment and the bit line contact may be omitted. The second channel segment 131B may be connected to the second bit line BL2 via the second doped capping segment and the bit line contact described with reference to FIGS. 4A and 4B. The present disclosure is not limited thereto, and at least one of the second doped capping segment and the bit line contact may be omitted.

The insulating pillar 135 may be formed of an insulating material such as silicon oxide. The channel separation structure 141 may be formed of an oxide of a semiconductor material.

The above-described first direction DR1 may be an X-axis direction, and the second direction DR2 and the third direction DR3 may be a +Y-axis direction and a −Y-axis direction. Hereinafter, a Z-axis direction may be referred to as a fourth direction DR4.

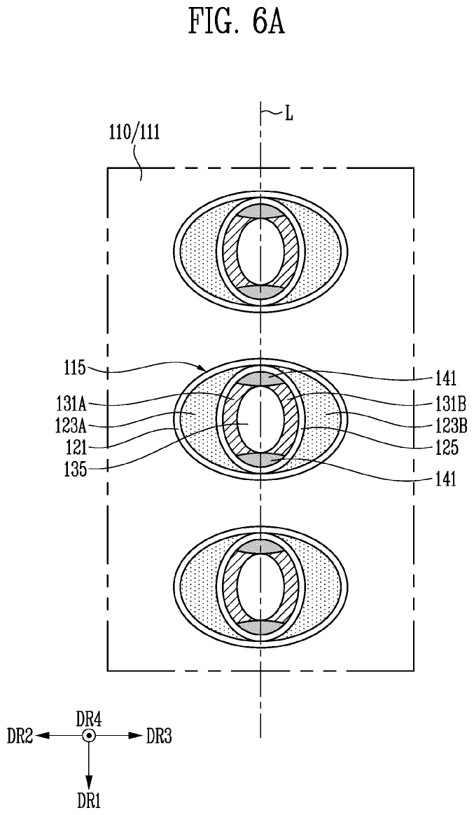

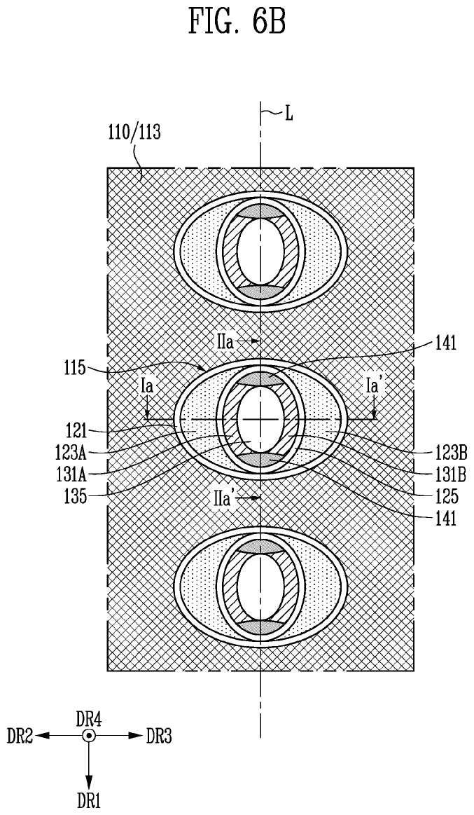

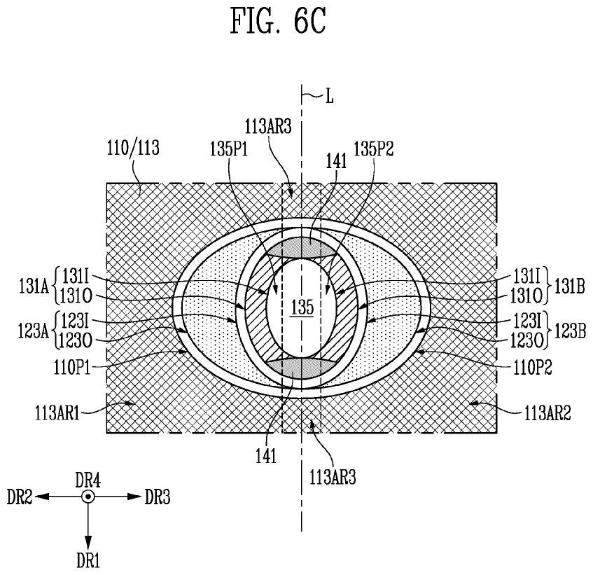

FIG. 6A is a plan view of a portion of a semiconductor memory device depicting where the interlayer insulating layer 111 shown in FIG. 5 is located.

FIG. 6B is a plan view of a different portion of the semiconductor memory device depicted in FIG. 6A, except at a different vertical level and whereat a conductive layer 113 shown in FIG. 5 is located.

FIG. 6C is an enlarged plan view of a portion of the structure shown in FIG. 6B.

Referring to FIGS. 6A to 6C, the conductive layer 113 of the gate stack 110 may overlap the interlayer insulating layer 111 of the gate stack 110 in the fourth direction DR4. The conductive layer 113 and the interlayer insulating layer 111 may be penetrated by the hole 115, in the fourth direction DR4, which is orthogonal to the plane of FIGS. 6A to 6C.

A first concave portion 110P1 and an opposite second concave portion 110P2 may be located inside the gate stack 110 and within the hole 115. The hole 115 may be formed such that its horizontal cross section has an elliptical shape on an X-Y plane. A straight line L of the hole 115 may overlap the minor axis of the elliptically-shaped hole 115. The straight line L may extend in the first direction DR1 on the X-Y plane.

The first concave portion 110P1 and the second concave portion 110P2 of the gate stack 110 may be curved in directions opposite to each other with respect to the straight line L. In one embodiment, the first concave portion 110P1 may be on one side of the hole 115 facing the second direction DR2. The second concave portion 110P2 may be on the opposite side of the hole 115 facing the third direction DR3.

The straight line L may geometrically bisect (not actually bisect) the elliptically-shaped insulating pillar 135. The insulating pillar 135 may include a first convex portion 135P1 and a second convex portion 135P2, which are curved in directions opposite to each other with respect to the straight line L. The major axis of the elliptically-shaped insulating pillar 135 is considered to be coincident with the straight line L. The first convex portion 135P1 may “face” the first concave portion 110P1 of the gate stack 110, and the second convex portion 135P2 may “face” the second concave portion 110P2 of the gate stack 110.

The first data storage segment 123A and the first channel segment 131A may be located between the first concave portion 110P1 of the gate stack 110 and the first convex portion 135P1 of the insulating pillar 135. The second data storage segment 123B and the second channel segment 131B may be located between the second concave portion 110P2 of the gate stack 110 and the second convex portion 135P2 of the insulating pillar 135.

The first channel segment 131A may extend along the first convex portion 135P1 of the insulating pillar 135, and the second channel segment 131B may extend along the second convex portion 135P2 of the insulating pillar 135. The first channel segment 131A and the second channel segment 131B may be insulated from each other by the channel separation structure 141. The channel separation structure 141 may extend from the insulating pillar 135 to between an end of the first channel segment 131A and an end of the second channel segment 131B.

The first data storage segment 123A may be located between the first channel segment 131A and the first concave portion 110P1 of the gate stack 110, and the second data storage segment 123B may be located between the second channel segment 131B and the second concave portion 110P2 of the gate stack 110. An edge of the first data storage segment 123A and an edge of the second data storage segment 123B may be aligned on a line forming an elliptical shape. Specifically, each of the first data storage segment 123A and the second data storage segment 123B may include an outer portion 123O facing the gate stack 110 and an inner portion 123I facing the insulating pillar 135. The outer portion 123O of the first data storage segment 123A and the outer portion 123O of the second data storage segment 123B may be aligned to contact an inner portion of an elliptically-shaped ring having a major axis facing the second direction DR2. The inner portion 123I of the first data storage segment 123A and the inner portion 123I of the second data storage segment 123B may be aligned to contact an outer portion of an elliptically-shaped ring having a major axis overlapping the straight line L.

Each of the first channel segment 131A and the second channel segment 131B may include an outer convex portion 131O facing the gate stack 110 and an inner concave portion 131I facing the insulating pillar 135. A distance between the outer portion 131O and the inner portion 131I may be maintained constant at a center and an end of each of the first channel segment 131A and the second channel segment 131B. Accordingly, a curvature of the outer portion 131O may be substantially the same as that of the inner portion 131I.

The blocking insulating layer 121 may extend around the inside surface of the hole 115 to form a first elliptically-shaped ring. The blocking insulating layer 121 may also be considered as being located between the first data storage segment 123A and the gate stack 110 and between the second data storage pattern 123B and the gate stack 110. The blocking insulating layer 121 may be formed to have a substantially constant thickness and width around its “circumference.” The outer portion 123O of the first data storage segment 123A and the outer portion 123O of the second data storage segment 123B may contact an inner surface or portion of the first elliptically-shaped ring.

The tunnel insulating layer 125 may be formed along the outer surface or the outer portion 131O of the first channel segment 131A and may extend around the outer surface or the outer portion 131O of the second channel segment 131B to form a second elliptically-shaped ring. The tunnel insulating layer 125 may be formed with a substantially constant thickness and width. The inner portion 123I of the first data storage segment 123A and the inner portion 123I of the second data storage segment 123B may contact the outer portion of the second elliptically-shaped ring.

The channel separation structure 141, the insulating pillar 135, the first channel segment 131A, and the second channel segment 131B may be located inside the elliptically-shaped ring formed by at least one of the tunnel insulating layer 125 and the blocking insulating layer 121. The first data storage segment 123A and the second data storage segment 123B may be located inside the first elliptically-shaped ring formed by the blocking insulating layer 121 but outside the second elliptically-shaped ring formed by the tunnel insulating layer 125.

Referring to FIG. 6C, the conductive layer 113 may include a first region 113AR1, a second region 113AR2, and a third region 113AR3. The first region 113AR1 may configure the first concave portion 110P1 and may surround an outer portion 123O of the first data storage segment 123A. The second region 113AR2 may configure the second concave portion 110P2 and may surround the outer portion 123O of the second data storage segment 123B. The third region 113AR3 may connect the first region 113AR1 and the second region 113AR2 and may face the channel separation structure 141.

The “width” of the first data storage segment 123A and the “width” of the second data storage segment 123B may decrease as the first and second date storage segment 123A and 123B close to the channel separation structure 141. Differently from an embodiment of the present disclosure, when the width of each of the first and second data storage segments is maintained uniformly, an electric field between each of the first channel segment 131A and the second channel segment 131B and the conductive layer 113 may decrease near the channel separation structure 141. According to an embodiment of the present disclosure, because the width of each of the first data storage segment 123A and the second data storage segment 123B becomes narrower as each of the first data storage segment 123A and the second data storage segment 123B is close to the channel separation structure 141, a phenomenon in which the electric field between each of the first channel segment 131A and the second channel segment 131B and the conductive layer 113 decreases near the channel separation structure 141 may be improved. Accordingly, operation reliability of the semiconductor memory device may be improved.

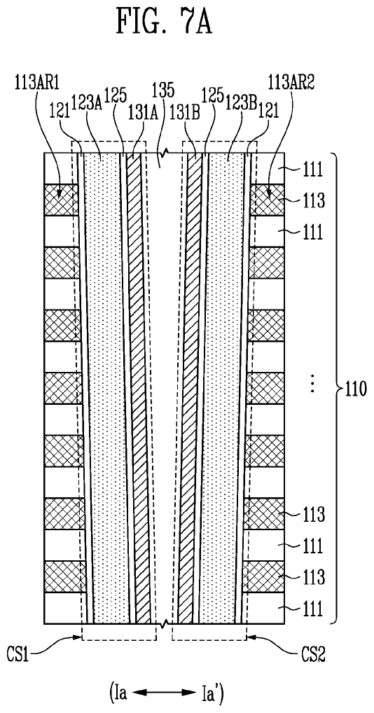

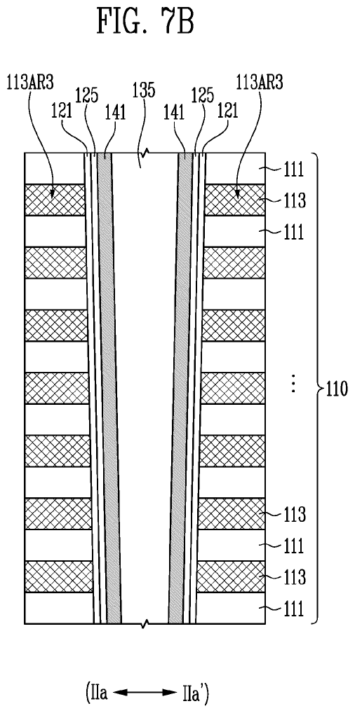

FIG. 7A is a vertical cross-sectional view of a gate stack of a semiconductor memory device taken along a section line Ia-Ia,′ shown in FIG. 6B. FIG. 7B is a different vertical cross-sectional view of the same gate stack but taken along section line IIa-IIa′, shown in FIG. 6B.

Referring to FIG. 7A, a first memory cell string CS1 and a second memory cell string CS2 may be formed on both “sides” of the insulating pillar 135 of the gate stack 110. The first channel segment 131A of the first memory cell string CS1 may be controlled by the first bit line 151A shown in FIG. 5, and the second channel segment 131B of the second memory cell string CS2 may be controlled by the second bit line 151B shown in FIG. 5.

Each conductive layer 113 of the gate stack 110 may be used as a word line. A plurality of first memory cells of the first memory cell string CS1 may be formed between the plurality of conductive layers 113 and the first channel segment 131A, and a plurality of second memory cells of the second memory cell string CS2 may be formed between the plurality of conductive layers 113 and the second channel segments 131B. A plurality of first data storage regions of the plurality of first memory cells may be formed inside the first data storage segment 123A. Each first data storage region may be a partial region of the first data storage segment 123A located between the first region 113AR1 of each conductive layer 113 and the first channel segment 131A. A plurality of second data storage regions of the plurality of second memory cells may be formed inside the second data storage segment 123B. Each second data storage region may be a partial region of the second data storage segment 123B disposed between the second region 113AR2 of each conductive layer 113 and the second channel segment 131B.

The blocking insulating layer 121 may located between the first data storage segment 123A and each of the interlayer insulating layer 111 and the conductive layer 113 and between the second data storage segment 123B and each of the interlayer insulating layer 111 and the conductive layer 113 to form the elliptically-shaped ring. The tunnel insulating layer 125 may located between the first data storage segment 123A and the first channel segment 131A and between the second data storage segment 123B and the second channel segment 131B to form the elliptically-shaped ring.

Referring to FIG. 7B, the channel separation structure 141 may contact the insulating pillar 135. The blocking insulating layer 121 and the tunnel insulating layer 125 may contact each other between the third region 113AR3 of each conductive layer 113 and the channel separation structure 141.

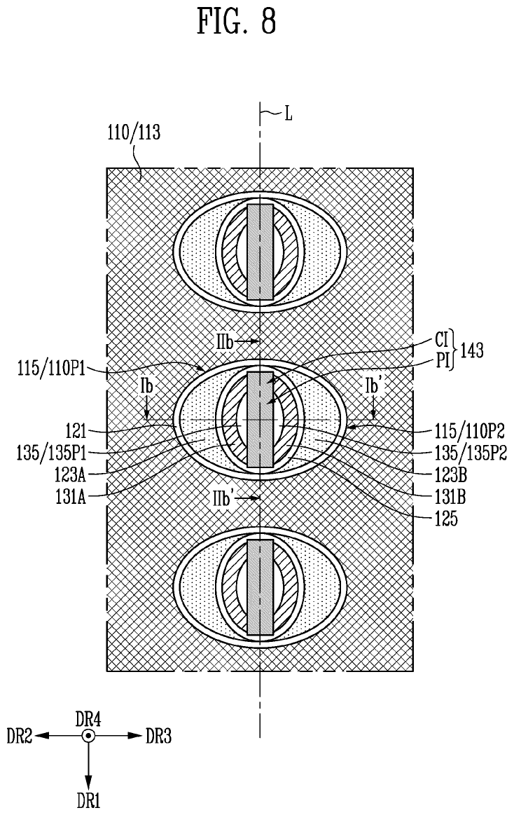

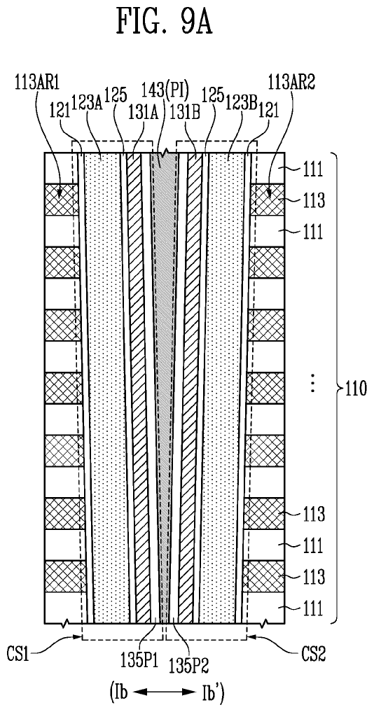

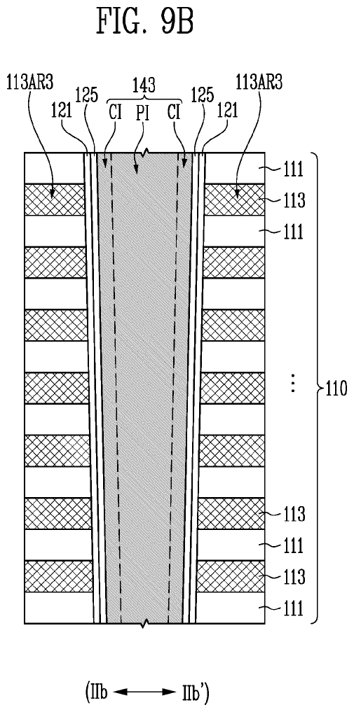

FIGS. 8, 9A, and 9B are diagrams illustrating a semiconductor memory device according to an embodiment of the present disclosure.

FIG. 8 is a horizontal cross section or “plan view,” of a gate stack of the semiconductor memory device. FIG. 9A is a vertical cross-sectional view of the gate stack taken along a line Ib-Ib′ shown in FIG. 8. FIG. 9B is a different vertical cross-sectional view of the gate stack taken along a line IIb-IIb′ shown in FIG. 8. Hereinafter, redundant descriptions for same structures shown in FIGS. 5, 6, 7A, and 7B are simplified or omitted in the interest of brevity.

Referring to FIGS. 8, 9A, and 9B, the gate stack 110 of the semiconductor memory device may include the hole 115, which may be formed in to have an elliptical cross-sectional shape thereby having a minor axis. The minor axis may be coincident with or “overlapping” the straight line L extending along the first direction DR1 and a major axis crossing the straight line L. The first concave portion 110P1 and the second concave portion 110P2 may be defined in the gate stack 110 by the hole 115. The first concave portion 110P1 and the second concave portion 110P2 may face the second direction DR2 and the third direction DR3 opposite to each other based on the straight line L.

The gate stack 110 may include the plurality of conductive layers 113. Vertically adjacent conductive layers 113 are spaced apart from each other in the fourth direction DR4 by an interlayer insulting layer 111 between vertically-adjacent conductive layers 113. The fourth direction DR4 may be the Z-axis direction, orthogonal to X and Y axes, and may be a direction crossing the geometric plane in which the straight line L is located. The gate stack 110 may further include a plurality of interlayer insulating layers 111. The insulating layers 111 may located alternately with the conductive layers 113 in the fourth direction DR4. Each insulating layer 111 between vertically-adjacent conductive layers 113.

The insulating pillar 135 including the first convex portion 135P1 and the second convex portion 135P2 may be located between the first concave portion 110P1 and the second concave portion 110P2 of the gate stack 110. The first convex portion 135P1 may face the first concave portion 110P1, and the second convex portion 135P2 may face the second concave portion 110P2.

A portion of the blocking insulating layer 121, the first data storage segment 123A, a portion of the tunnel insulating layer 125, and the first channel segment 131A may be located between the first concave portion 110P1 of the gate stack 110 and the first convex portion 135P1 of the insulating pillar 135. Another portion of the blocking insulating layer 121, the second data storage segment 123B, another portion of the tunnel insulating layer 125, and the second channel segment 131B may be located between the second concave portion 110P2 of the gate stack 110 and the second convex portion 135P2 of the insulating pillar 135.

An insulating segment 143 may be located inside the hole 115. The insulating segment 143 may include an insulating material such as silicon oxide. The insulating segment 143 may overlap the straight line L and the minor axis of the hole 115. The insulating segment 143 may be an integrated segment. A portion of the insulating segment 143 may be used as a channel separation structure CI, and another portion may be used as a pillar separation structure PI. The channel separation structure CI of the insulating segment 143 may be located between the end of the first channel segment 131A and the end of the second channel segment 131B. The pillar separation structure PI may extend to between the first convex portion 135P1 and the second convex portion 135P2 of the insulating pillar 135 to pass through the insulating pillar 135 from the channel separation structure CI.

The blocking insulating layer 121 may extend to between the channel separation structure CI of the insulating segment 143 and the gate stack 110. The tunnel insulating layer 125 may extend to between the channel separation structure CI of the insulating segment 143 and the gate stack 110.

Each of the conductive layers 113 may include the first region 113AR1 having the first concave portion 110P1, the second region 113AR2 having the second concave portion 110P2, and the third region 113AR3 connecting the first region 113AR1 and the second region 113AR2. The conductive layer 113 may control the first memory cell string CS1 formed on a side of the first region 113AR1 and the second memory cell string CS2 formed on a side of the second region 113AR2. The first channel segment 131A of the first memory cell string CS1 and the second channel segment 131B of the second memory cell string CS2 may be individually controlled by the first bit line 151A and the second bit line 151B shown in FIG. 5.

The channel separation structure PI of the insulating segment 143 may contact the tunnel insulating layer 125 or the blocking insulating layer 121 between the pillar separation structure CI and the third region AR3 of the conductive layer 113.

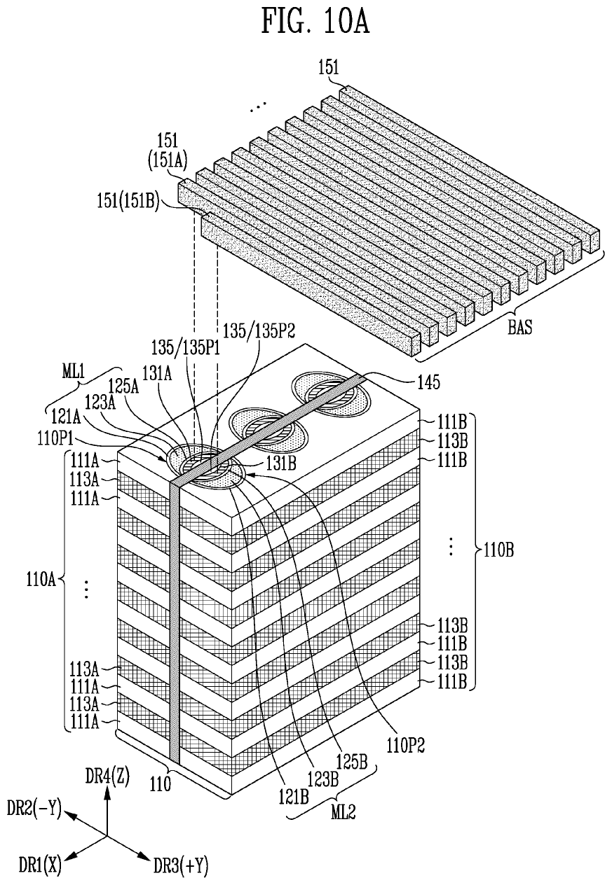

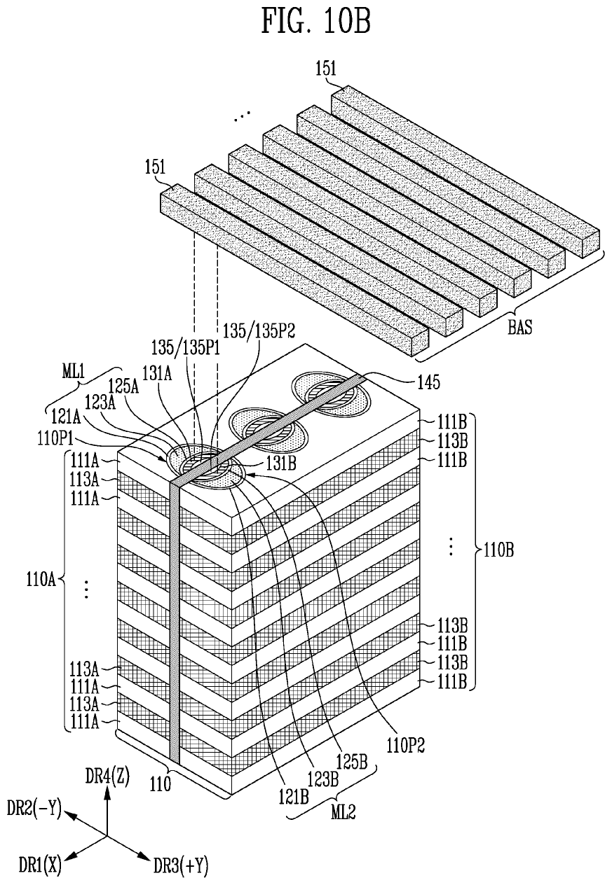

FIGS. 10A and 10B are diagrams illustrating semiconductor memory devices according to embodiments of the present disclosure.

Referring to FIGS. 10A and 10B, a semiconductor memory device may include a gate stack 110, an insulating pillar 135, an insulating segment 145, a first memory segment ML1, a second memory segment ML2, a first channel segment 131A, a second channel segment 131B, and a bit line array structure BAS.

The gate stack 110 may be partitioned by the slit SI shown in FIG. 5. The gate stack 110 may include a first sub-stack 110A and a second sub-stack 110B adjacent to each other. The first sub-stack 110A may include a plurality of first conductive layers 113A spaced apart from each other and stacked in the Z-axis direction, and the second sub-stack 110B may include a plurality of second conductive layers 113B spaced apart from each other and stacked in the Z-axis direction. The first sub-stack 110A may further include a plurality of first interlayer insulating layers 111A located alternately with the plurality of first conductive layers 113A in the Z-axis direction, and the second sub-stack 110B may further include a plurality of second interlayer insulating layers 111B located alternately with the plurality of second conductive layers 113B in the Z-axis direction. Each of the plurality of first conductive layers 113A, the plurality of second conductive layers 113B, the plurality of first interlayer insulating layers 111A, and the plurality of second interlayer insulating layers 111B may be formed in a plate shape extending along the plane crossing the Z-axis. Each of the plurality of first conductive layers 113A and the plurality of second conductive layers 113B may be used as the word line WL shown in FIG. 2.

The plurality of first conductive layers 113A and the plurality of second conductive layers 113B may include various conductive materials exemplified as the material of the plurality of conductive layers 113 shown in FIG. 5. The plurality of first interlayer insulating layers 111A and the plurality of second interlayer insulating layers 111B may include a silicon oxide layer or the like.

The insulating pillar 135 may be located between the first sub-stack 110A and the second sub-stack 110B. The insulating pillar 135 may be formed of an insulating material such as silicon oxide. The insulating pillar 135 may include the first convex portion 135P1 and the second convex portion 135P2. A curved side portion of the first convex portion 135P1 may be surrounded by the first sub-stack 110A, and a curved side portion of the second convex portion 135P2 may be surrounded by the second sub-stack 110B.

The insulating segment 145 may be formed of an insulating material identical to or different from that of the insulating pillar 135. The insulating segment 145 may cross between the first convex portion 135P1 and the second convex portion 135P2 of the insulating pillar 135 and extend to between the first sub-stack 110A and the second sub-stack 110B. The insulating segment 145 may extend in the first direction DR1 on the plane. The first direction DR1 may be the X-axis direction. The insulating segment 145 may extend in the Z-axis direction to insulate the plurality of first conductive layers 113A of the first sub-stack 110A from the plurality of second conductive layers 113B of the second sub-stack 110B.

A first sub-stack 110A of the gate stack 110 may include a first concave portion 110P1. A second sub-stack 110B of the gate stack 110 may include a second concave portion 110P2. The first concave portion 110P1 and the second concave portion 110P2 may be concave, i.e., curved, in the second direction DR2 and the third direction DR3 opposite to each other on the geometric plane. The second direction DR2 may be a −Y axis direction, and the third direction DR3 may be a +Y axis direction. Hereinafter, the Z-axis direction is referred to as a fourth direction DR4. The first convex portion 135P1 of the insulating pillar 135 may be convex toward the first concave portion 110P1 of the first sub-stack 110A, and the second convex portion 135P2 of the insulating pillar 135 may be convex toward the second concave portion 110P2 of the second sub-stack 110B.

The first memory segment ML1 and the first channel segment 131A may be located between the first concave portion 110P1 of the first sub-stack 110A and the first convex portion 135P1 of the insulating pillar 135. The first memory segment ML1 may include a first blocking insulating segment 121A, a first data storage segment 123A, and a first tunnel insulating segment 125A.

The second memory segment ML2 and the second channel segment 131B may be located between the second concave portion 110P2 of the second sub-stack 110B and the second convex portion 135P1 of the insulating pillar 135. The second memory segment ML2 may include a second blocking insulating segment 121B, a second data storage segment 123B, and a second tunnel insulating segment 125B.

The first blocking insulating segment 121A and the second blocking insulating segment 121B may be formed of the same material as the blocking insulating layer 121 shown in FIG. 5, and the first tunnel insulating segment 125A and the second tunnel insulating segment 125B may be formed of the same material as the tunnel insulating layer 125 shown in FIG. 5. The first data storage segment 123A and the second data storage segment 123B may be formed of various materials exemplified in FIG. 5. The first data storage segment 123A and the second data storage segment 123B may be formed in a structure the same as that described with reference to FIG. 5.

Each of the first channel segment 131A and the second channel segment 131B may be formed of the same material as that described with reference to FIG. 5. The first channel segment 131A and the second channel segment 131B may be connected to the plurality of bit lines 151 of the bit line array structure BAS in various methods.

Referring to FIG. 10A, the plurality of bit lines 151 may include a first bit line 151A connected to the first channel segment 131A and a second bit line 151B connected to the second channel segment 131B. According to this, the first channel segment 131A may be controlled by the first bit line 151A and the first conductive layer 113A, and the second channel segment 131B may be controlled by the second bit line 151B and the second conductive layer 113B.

Referring to FIG. 10B, each bit line 151 of the plurality of bit lines 151 may be connected to the first channel segment 131A and the second channel segment 131B facing each other. The first channel segment 131A and the second channel segment 131B connected to the same bit line 151 may be individually controlled by the first conductive layer 113A and the second conductive layer 113B.

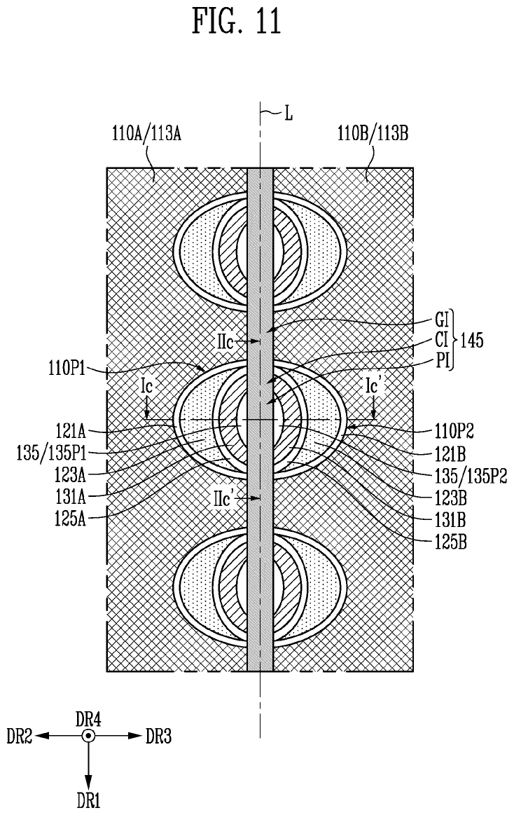

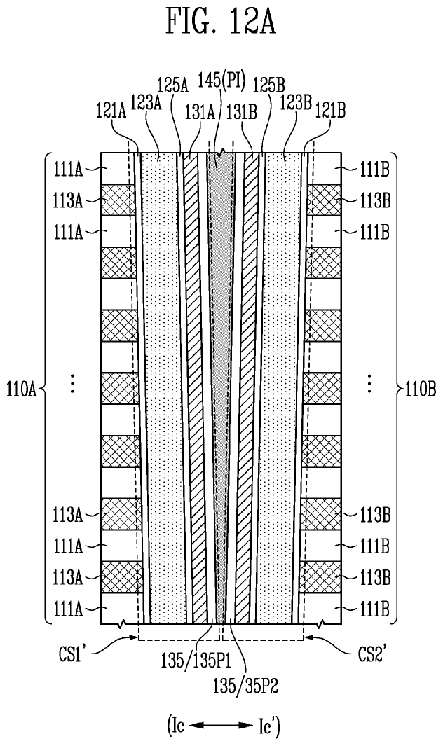

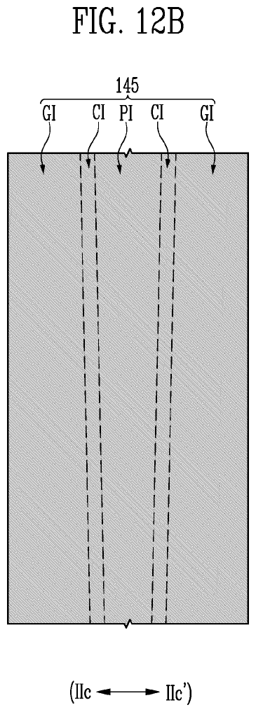

FIGS. 11, 12A, and 12B are diagrams illustrating a semiconductor memory device shown in FIG. 10A or 10B.

FIG. 11 is a plan view of the gate stack of semiconductor memory device shown in FIG. 10A or 10B.

Referring to FIG. 11, the straight line L may be defined as the first direction DR1 along the insulating segment 145. The first concave portion 110P1 of the first sub-stack 110A and the second concave portion 110P2 of the second sub-stack 110B may overlap on a line extending along an elliptical shape having a minor axis overlapping the straight line L and a major axis crossing the straight line L.

The first data storage segment 123A, the first channel segment 131A, the second data storage segment 123B, and the second channel segment 131B may be formed in a structure the same as that described with reference to FIGS. 6A to 6C.

The insulating segment 145 may be an integrated segment including the channel separation structure CI, the gate separation structure GI, and the pillar separation structure PI. The channel separation structure CI may be located between an end of the first channel segment 131A and an end of the second channel segment 131B. The channel separation structure CI may pass between the first tunnel insulating segment 125A and the second tunnel insulating segment 125B and extend to between the first blocking insulating segment 121A and the second blocking insulating segment 121B. The gate separation structure GI may extend from the channel separation structure CI between the first sub-stack 110A and the second sub-stack 110B. The first conductive layer 113A of the first sub-stack 110A and the second conductive layer 113B of the second sub-stack 110B may be insulated from each other by the gate separation structure GI. The pillar separation structure PI may extend from the channel separation structure CI between the first convex portion 135P1 and the second convex portion 135P2 of the insulating pillar 135 and pass through the insulating pillar 135.

The first conductive layer 113A may configure the first concave portion 110P1 of the first sub-stack 110A, and the second conductive layer 113B may configure the second concave portion 110P2 of the second sub-stack 110B.

A width of each of the first data storage segment 123A and the second data storage segment 123B may become narrower as each of the first data storage segment 123A and the second data storage segment 123B is closer to the channel separation structure CI of the insulating segment 145 or the gate separation structure GI of the insulating segment 145. Accordingly, a phenomenon in which an electric field between the first channel segment 131A and the first conductive layer 113A and an electric field between the second channel segment 131B and the second conductive layer 113B is reduced near the channel separation structure CI or the gate separation structure GI of the insulating segment 145 may be improved, and thus operation reliability of the semiconductor memory device may be improved.

FIG. 12A is a vertical cross-sectional view of the gate stack of a semiconductor memory device taken along a line Ic-Ic′ shown in FIG. 11, and FIG. 12B is a vertical cross-sectional view of the gate stack of a semiconductor memory device taken along a line IIc-IIc′ shown in FIG. 11.

Referring to FIGS. 12A and 12B, a first memory cell string CS1′ may be formed between the first sub-stack 110A and the first convex portion 135P1 of the insulating pillar 135, and a second memory cell string CS2′ may be formed between the second sub-stack 110B and the second convex portion 135P2 of the insulating pillar 135. The gate separation structure GI, the channel separation structure CI, and the pillar separation structure PI aligned in a row may separate the first blocking insulating segment 121A, the first data storage segment 123A, the first tunnel insulating segment 125A, and the first channel segment 131A of the first memory cell string CS1′ from the second blocking insulating segment 121B, the second data storage segment 123B, the second tunnel insulating segment 125B, and the second channel segment 131B of the second memory cell string CS2′. Accordingly, because interference between operations of the first memory cell string CS1′ and the second memory cell string CS2′ may be reduced, operation reliability of the semiconductor memory device may be improved.

The first conductive layer 113A of the first sub-stack 110A and the second conductive layer 113B of the second sub-stack 110B may be separated from each other by the insulating segment 145. The first interlayer insulating layer 111A of the first sub-stack 110A and the second interlayer insulating layer 111B of the second sub-stack 110B may be separated from each other by the insulating segment 145.

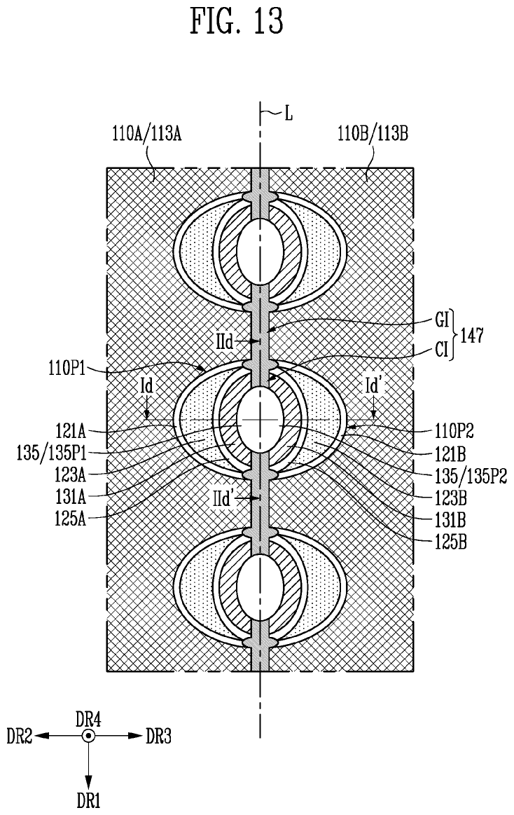

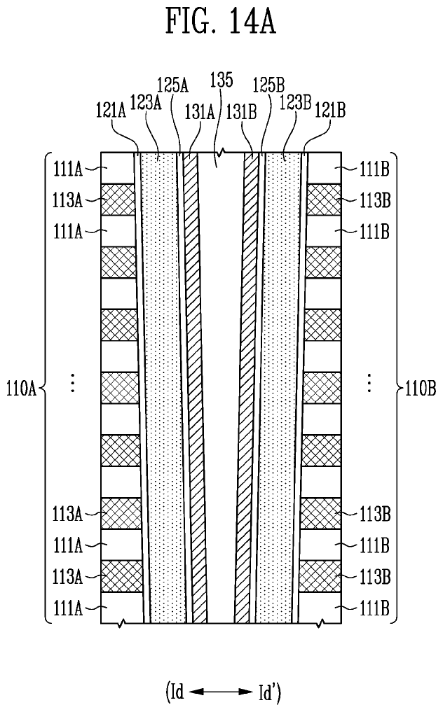

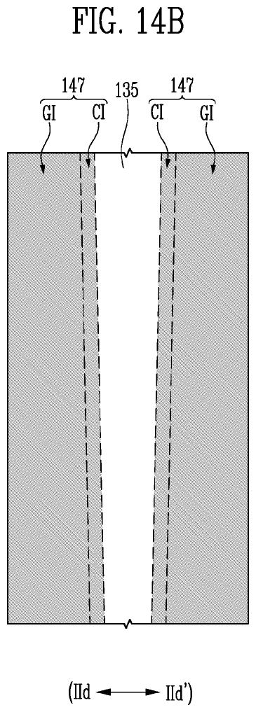

FIGS. 13, 14A, and 14B are diagrams illustrating a semiconductor memory device according to an embodiment of the present disclosure.

FIG. 13 is a plan view of the gate stack of the semiconductor memory device. FIG. 14A is a cross-sectional view of the gate stack of the semiconductor memory device taken along a line Id-Id′ shown in FIG. 13, and FIG. 14B is a cross-sectional view of the semiconductor memory device gate stack taken along a line IId-IId′ shown in FIG. 13. Hereinafter, an overlapping description for configurations the same as those shown in FIGS. 10A, 10B, 11, 12A, and 12B is simplified or omitted.

Referring to FIGS. 13, 14A, and 14B, the first sub-stack 110A of the gate stack and the second sub-stack 110B of the gate stack may be separated from each other by the insulating pillar 135 and an insulating segment 147 extended from the insulating pillar 135. The insulating pillar 135 and the insulating segment 147 may be aligned on the straight line L extending in the first direction DR1 on the plane. The insulating pillar 135 and the insulating segment 147 may be alternately located in the first direction DR1.

The insulating pillar 135 may include the first convex portion 135P1 and the second convex portion 135P2 convex in the second direction DR2 and the third direction DR3 opposite to each other on the plane. The insulating pillar 135 may extend to between insulating segments 147 adjacent in the first direction DR1.

The first sub-stack 110A may include the plurality of first interlayer insulating layers 111A and the plurality of first conductive layers 113A. The plurality of first interlayer insulating layers 111A and the plurality of first conductive layers 113A may be alternately located in the fourth direction DR4 crossing the plane where the straight line L is located. The first sub-stack 110A may include the first concave portion 110P1 corresponding to the first convex portion 135P1 of the insulating pillar 135.

The first channel segment 131A may be located between the first concave portion 110P1 of the first sub-stack 110A and the first convex portion 135P1 of the insulating pillar 135. The first data storage segment 123A may be located between the first concave portion 110P1 of the first sub-stack 110A and the first channel segment 131A. The first tunnel insulating segment 125A may be located between the first data storage segment 123A and the first channel segment 131A.

The second sub-stack 110B may include the plurality of second interlayer insulating layers 111B and the plurality of second conductive layers 113B alternately located in the fourth direction DR4. The second sub-stack 110B may include the second concave portion 110P2 corresponding to the second convex portion 135P2 of the insulating pillar 135.

The second channel segment 131B may be located between the second concave portion 110P2 of the second sub-stack 110B and the second convex portion 135P2 of the insulating pillar 135. The second data storage segment 123B may be located between the second concave portion 110P2 of the second sub-stack 110B and the second channel segment 131B. The second tunnel insulating segment 125B may be located between the second data storage segment 123B and the second channel segment 131B.

The insulating segment 147 may be formed of an insulating material identical to or different from that of the insulating pillar 135. The insulating segment 147 may be an integrated segment including the channel separation structure CI and the gate separation structure GI. The channel separation structure CI may cross between the end of the first channel segment 131A and the end of the second channel segment 131B from the insulating pillar 135, and extend to between the first blocking insulating segment 121A and the second blocking insulating segment 121B. The gate separation structure GI may extend from the channel separation structure CI to between the first sub-stack 110A and the second sub-stack 110B.

The first channel segment 131A and the second channel segment 131B may be individually connected to the first bit line 151A and the second bit line 151B shown in FIG. 10A, or may be connected to the same bit line 151 as shown in FIG. 10B.

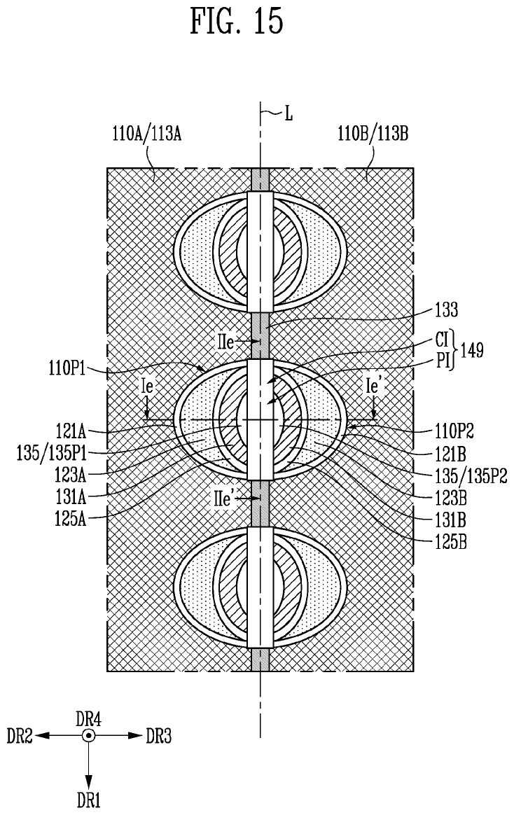

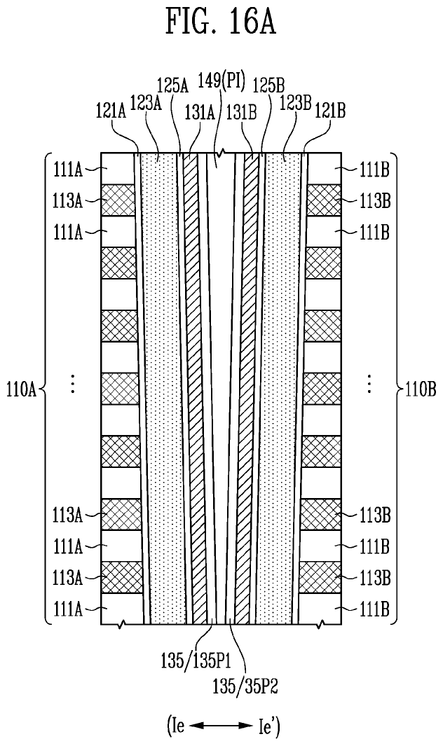

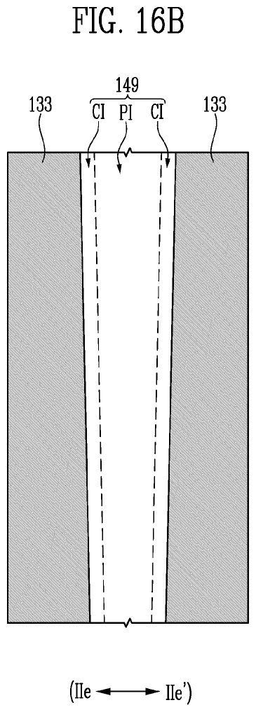

FIGS. 15, 16A, and 16B are diagrams illustrating a semiconductor memory device according to an embodiment of the present disclosure.

FIG. 15 is a plan view of the gate stack of the semiconductor memory device. FIG. 16A is a cross-sectional view of the gate stack of the semiconductor memory device taken along a line Ie-Ie′ shown in FIG. 15, and FIG. 16B is a cross-sectional view of the gate stack of the semiconductor memory device taken along a line Ile-Ile′ shown in FIG. 15. Hereinafter, an overlapping description for configurations the same as those shown in FIGS. 10A, 10B, 11, 12A, and 12B is simplified or omitted.

Referring to FIGS. 15, 16A, and 16B, the first sub-stack 110A of the gate stack and the second sub-stack 110B of the gate stack may be separated from each other by an insulating segment 149 and a gate separation structure 133 extended from the insulating segment 149. The insulating segment 149 and the gate separation structure 133 may be aligned on the straight line L extending in the first direction DR1 on the plane. The insulating segment 149 and the gate separation structure 133 may be alternately located in the first direction DR1.

The insulating pillar 135 may include the first convex portion 135P1 and the second convex portion 135P2 convex in the second direction DR2 and the third direction DR3 opposite to each other on the plane where the straight line L is located. The first convex portion 131P1 and the second convex portion 131P2 may be separated by the insulating segment 149.

The first sub-stack 110A may include the plurality of first interlayer insulating layers 111A and the plurality of first conductive layers 113A. The plurality of first interlayer insulating layers 111A and the plurality of first conductive layers 113A may be alternately located in the fourth direction DR4 crossing the plane where the straight line L is located. The first sub-stack 110A may include the first concave portion 110P1 corresponding to the first convex portion 135P1 of the insulating pillar 135.

The first channel segment 131A may be located between the first concave portion 110P1 of the first sub-stack 110A and the first convex portion 135P1 of the insulating pillar 135. The first data storage segment 123A may be located between the first concave portion 110P1 of the first sub-stack 110A and the first channel segment 131A. The first tunnel insulating segment 125A may be located between the first data storage segment 123A and the first channel segment 131A.

The second sub-stack 110B may include the plurality of second interlayer insulating layers 111B and the plurality of second conductive layers 113B alternately located in the fourth direction DR4. The second sub-stack 110B may include the second concave portion 110P2 corresponding to the second convex portion 135P2 of the insulating pillar 135.

The second channel segment 131B may be located between the second concave portion 110P2 of the second sub-stack 110B and the second convex portion 135P2 of the insulating pillar 135. The second data storage segment 123B may be located between the second concave portion 110P2 of the second sub-stack 110B and the second channel segment 131B. The second tunnel insulating segment 125B may be located between the second data storage segment 123B and the second channel segment 131B.

The gate separation structure 133 may contact the insulating segment 149 and extend to between the first sub-stack 110A and the second sub-stack 110B. The gate separation structure 133 may be formed of an insulating material identical to or different from that of the insulating segment 149.

The insulating segment 149 may be an integrated segment including the channel separation structure CI and the pillar separation structure PI. The channel separation structure CI may cross between the first blocking insulating segment 121A and the second blocking insulating segment 121B from the gate separation structure 133, and extend to between the end of the first channel segment 131A and the end of the second channel segment 131B. The pillar separation structure PI may extend from the channel separation structure CI to between the first convex portion 135P1 and the second convex portion 135P2 of the insulating pillar 135.

The first channel segment 131A and the second channel segment 131B may be individually connected to the first bit line 151A and the second bit line 151B shown in FIG. 10A, or may be connected to the same bit line 151 as shown in FIG. 10B.

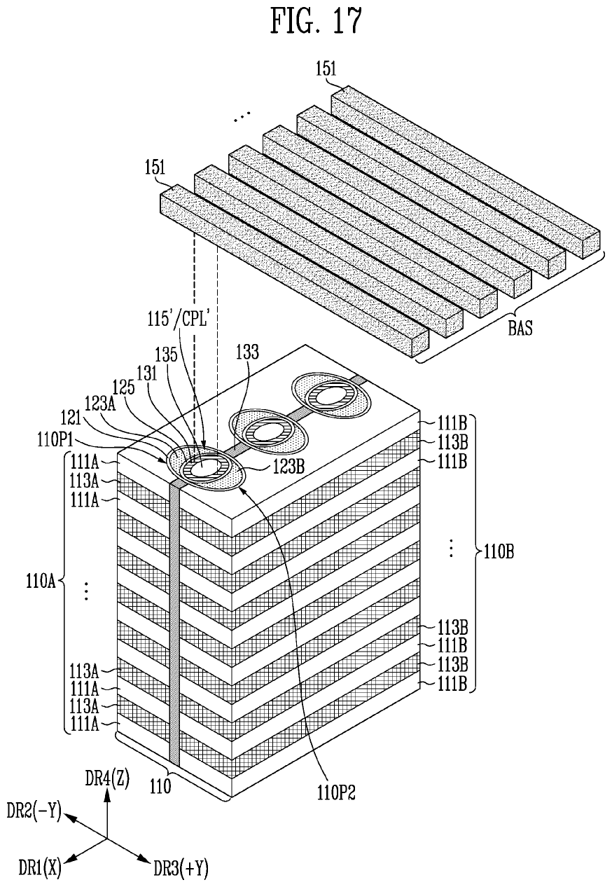

FIGS. 17, 18, 19A, and 19B are diagrams illustrating a semiconductor memory device according to an embodiment of the present disclosure.

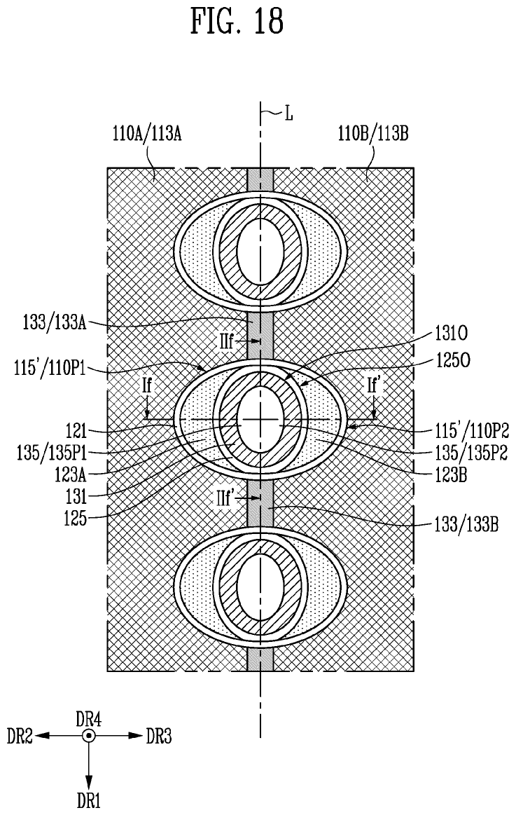

FIG. 17 is an exploded perspective view illustrating a portion of a gate stack of the semiconductor memory device and a gate stack. FIG. 18 is a plan view of the gate stack of the semiconductor memory device shown in FIG. 17.

Referring to FIGS. 17 and 18, the semiconductor memory device may include the gate stack 110, the gate separation structure 133, a cell plug CPL′, and the bit line array structure BAS.

The gate stack 110 may be partitioned by the slit SI shown in FIG. 5. The gate stack 110 may include the first sub-stack 110A and the second sub-stack 110B adjacent to each other. The first sub-stack 110A may include the plurality of first conductive layers 113A spaced apart from each other and stacked in the Z-axis direction, and the second sub-stack 110B may include the plurality of second conductive layers 113B spaced apart from each other and stacked in the Z-axis direction. The first sub-stack 110A may further include the plurality of first interlayer insulating layers 111A located alternately with the plurality of first conductive layers 113A in the Z-axis direction, and the second sub-stack 110B may further include the plurality of second interlayer insulating layers 111B located alternately with the plurality of second conductive layers 113B in the Z-axis direction. Each of the plurality of first conductive layers 113A, the plurality of second conductive layers 113B, the plurality of first interlayer insulating layers 111A, and the plurality of second interlayer insulating layers 111B may be formed in a plate shape extending along the plane crossing the Z-axis. Each of the plurality of first conductive layers 113A and the plurality of second conductive layers 113B may be used as the word line WL shown in FIG. 2.

The plurality of first conductive layers 113A and the plurality of second conductive layers 113B may include various conductive materials exemplified as the material of the plurality of conductive layers 113 shown in FIG. 5. The plurality of first interlayer insulating layers 111A and the plurality of second interlayer insulating layers 111B may include a silicon oxide layer or the like.

The first sub-stack 110A and the second sub-stack 110B may be separated from each other by the cell plug CPL′ and the gate separation structure 133. The cell plug CPL′ and the gate separation structure 133 may be alternately located in the first direction DR1 on the straight line L extending in the first direction DR1 on the plane. The first direction DR1 may be the X-axis direction.

The cell plug CPL′ may be located inside a hole 115′ of the gate stack 110. The hole 115′ may be formed along a side portion of the first concave portion 110P1 of the first sub-stack 110A, the second concave portion 110P2 of the second sub-stack 110B, and the gate separation structure 133. The hole 115′ may be formed in an elliptical shape on the plane where the straight line L is located. A minor axis of the elliptical shape defined by the hole 115′ may overlap the straight line L.

The first concave portion 110P1 of the first sub-stack 110A may form a portion of the hole 115′ facing the second direction DR2 on the plane where the straight line L is located. The second concave portion 110P2 of the second sub-stack 110B may form another portion of the hole 115′ facing the third direction DR3 on the plane where the straight line L is located. The second direction DR2 and the third direction DR3 may be directions opposite to each other. The second direction DR2 may be the −Y axis direction, and the third direction DR3 may be the +Y axis direction. Hereinafter, the Z-axis direction is referred to as the fourth direction DR4.

The cell plug CPL′ may include the insulating pillar 135, a channel layer 131, the tunnel insulating layer 125, the first data storage segment 123A, a second data storage segment 123B, and the blocking insulating layer 121. The cell plug CPL′ may be located between the first concave portion 110P1 of the first sub-stack 110A and the second concave portion 110P2 of the second sub-stack 110B.

The insulating pillar 135 may be located on the straight line L at a center of the cell plug CPL′. The insulating pillar 135 may be formed of an insulating material such as silicon oxide. The insulating pillar 135 may include the first convex portion 135P1 and the second convex portion 135P2. The first convex portion 135P1 and the second convex portion 135P2 may be convex in the second direction DR2 and the third direction DR3 opposite based on the straight line L. The curved side portion of the first convex portion 135P1 may face the first concave portion 110P1 of the first sub-stack portion 110A and may be surrounded by the first sub-gate stack 110A. The curved side portion of the second convex portion 135P2 may face the second concave portion 110P2 of the second sub-stack 110B and may be surrounded by the second sub-gate stack 110B. The insulating pillar 135 may be spaced apart from the gate separation structure 133 on the straight line L, and may be located alternately with the gate separation structure 133 in the first direction DR1. For example, the insulating pillar 135 of the cell plug CPL′ may be located between the first gate separation structure 133A and the second gate separation structure 133B adjacent to each other in the first direction DR1.

The first data storage segment 123A may be located between the first convex portion 135P1 of the insulating pillar 135 and the first concave portion 110P1 of the first sub-stack 110A. The second data storage segment 123B may be located between the second convex portion 135P2 of the insulating pillar 135 and the second concave portion 110P2 of the second sub-stack 110B. The first data storage segment 123A and the second data storage segment 123B may be formed of various materials exemplified in FIG. 5. An edge of the first data storage segment 123A and an edge of the second data storage segment 123B may be aligned on a line forming an elliptical shape.

The channel layer 131 may be located between the first data storage segment 123A and the first convex portion 135P1 of the insulating pillar 135. The channel layer 131 may pass between the gate separation structure 133 and the insulating pillar 135 and successively extend to between the second data storage segment 123B and the second convex portion 135P2 of the insulating pillar 135. According to this, the channel layer 131 may form an elliptically-shaped ring on the plane where the straight line L is located. A major axis of the elliptically-shaped ring formed by the channel layer 131 may overlap the straight line L together with a minor axis of an elliptical shape formed by the hole 115′. A minor axis of the elliptically-shaped ring formed by the channel layer 131 may overlap a major axis of the elliptical shape formed by the hole 115′. The channel layer 131 may be formed of the same material as the first channel segment 131A and the second channel segment 131B shown in FIG. 5.

The tunnel insulating layer 125 may cover an outer portion 131O of the channel layer 131, and the blocking insulating layer 121 may cover an outer portion 1250 of the tunnel insulating layer 125. The blocking insulating layer 121 may successively extend to be located between the first data storage segment 123A and the first concave portion 110P1 of the first sub-stack 110A, between the gate separation structure 133 and the tunnel insulating layer 125, and between the second data storage segment 123B and the second concave portion 110P2 of the second sub-stack 110B. According to this, the blocking insulating layer 121 may form a first elliptically-shaped ring. The tunnel insulating layer 125 may successively extend along the outer portion 131O of the channel layer 131 to form a second elliptically-shaped ring. A minor axis of the first elliptically-shaped ring and a major axis of the second elliptically-shaped ring may overlap the straight line L. A major axis of the first elliptically-shaped ring may overlap a minor axis of the second elliptically-shaped ring. The tunnel insulating layer 125 and the blocking insulating layer 121 may be formed of the same materials as that described with reference to FIG. 5.

The gate separation structure 133 may be formed of various insulating materials. The gate separation structure 133 may contact the tunnel insulating layer 123 and may extend to between the first sub-stack 110A and the second sub-stack 110B.

The width of each of the first data storage segment 123A and the second data storage segment 123B may become narrower as each of the first data storage segment 123A and the second data storage segment 123B is close to the gate separation structure 133. According to an embodiment of the present disclosure, because the width of each of the first data storage segment 123A and the second data storage segment 123B becomes narrower as each of the first data storage segment 123A and the second data storage segment 123B is close to the gate separation structure 133, a phenomenon in which an electric field between each of the first conductive layer 113A and the second conductive layer 113B and the channel layer 131 is reduced near the gate separation structure 133 may be improved. Accordingly, operation reliability of the semiconductor memory device may be improved.

The bit line array structure BAS may include the plurality of bit lines 151. Each bit line 151 may be connected to the channel layer 131 corresponding thereto.

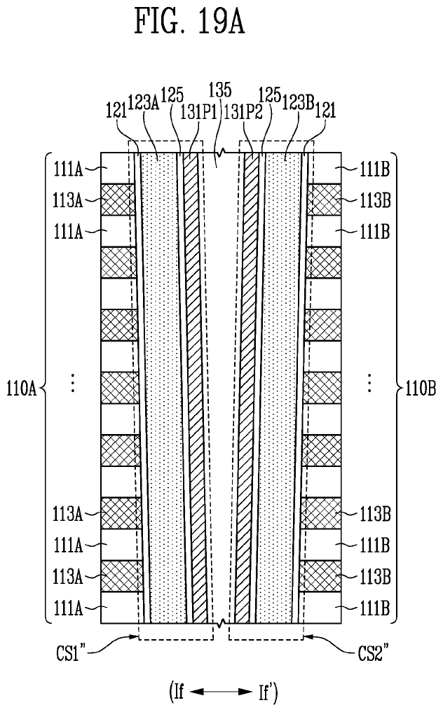

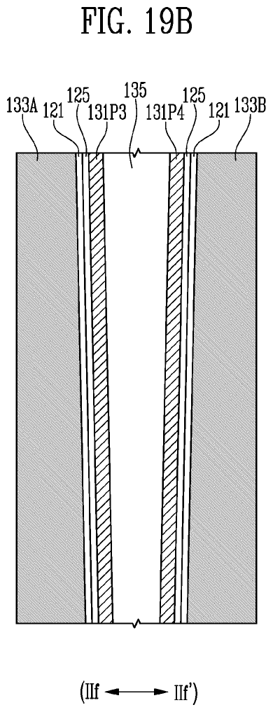

FIG. 19A is a cross-sectional view of a gate stack of a semiconductor memory device taken along a line If-If′ shown in FIG. 18, and FIG. 19B is a cross-sectional view of the semiconductor memory device gate stack taken along a line IIf-Iif′ shown in FIG. 18.

Referring to FIGS. 18, 19A, and 19B, the channel layer 131 may include first to fourth portions 131P1 to 131P4 connected to each other. The first portion 131P1 may be located between the insulating pillar 135 and the first sub-stack 110A, and the second portion 131P2 may be located between the insulating pillar 135 and the second sub-stack 110B. The third portion 131P3 may be located between the first gate separation structure 133A and the insulating pillar 135, and the fourth portion 131P4 may be located between the second gate separation structure 133B and the insulating pillar 135.

The first portion 131P1 of the channel layer 131 may be used as a channel region of a first memory cell string CS1″, and the second portion 131P2 of the channel layer 131 may be used as a channel region of a second memory cell string CS2″. The blocking insulating layer 121 and the tunnel insulating layer 125 may be located between the first gate separation structure 133A and the third portion 131P3 of the channel layer 131, and may be located between the second gate separation structure 133B and the fourth portion 131P4 of the channel layer 131. The first gate separation structure 133A and the second gate separation structure 133B may contact the blocking insulating layer 121 to separate the first sub-stack 110A from the second sub-stack 110B. Accordingly, the plurality of first conductive layers 113A controlling the first memory cell string CS1″ may be separated from the plurality of second conductive layers 113B controlling the second memory cell string CS2″. The plurality of first interlayer insulating layers 111A may be separated from the plurality of second interlayer insulating layers 111B by a connection structure of the first gate separation structure 133A, the second gate separation structure 133B, the blocking insulating layer 121, and the tunnel insulating layer 125.

In the embodiments shown in FIGS. 5 to 19B, a structure in which each of the blocking insulating layer and the first and second blocking insulating segments is formed by extending to a side portion of the interlayer insulating layer, the first interlayer insulating layer, or the second interlayer insulating layer is disclosed, but the present disclosure is not limited thereto. Although not shown in the drawings, each of the blocking insulating layer and the first and second blocking insulating segments may be separated into an upper segment and a lower segment adjacent to each other in the Z-axis direction with the interlayer insulating layer, the first interlayer insulating layer, or the second interlayer insulating layer located therebetween.

The first data storage segment 123A and the second data storage segment 123B of the semiconductor memory device described with reference to FIGS. 5 to 19B may be formed using a hole having an elliptical cross-sectional structure. In forming the hole, a case where a cross section of the hole has an elliptical shape may reduce distortion of a hole shape compared to a case where the cross section of the hole has a concavo-convex shape. Hereinafter, a method of manufacturing a semiconductor memory device according to various embodiments capable of increasing stability of the method of manufacturing the semiconductor memory device by reducing distortion of the hole shape is described.

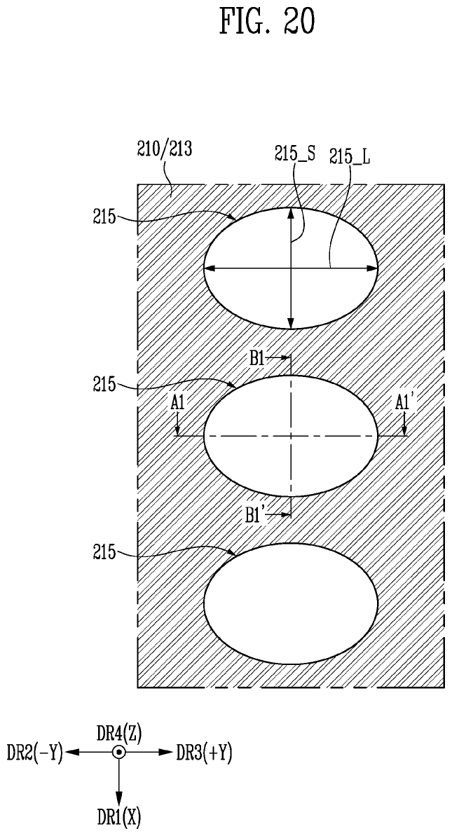

FIGS. 20, 21A, 21B, 22A, 22B, 23A, 23B, 24A, 24B, 25A, 25B, 26, 27A, 27B, 28A, 28B, 29A, 29B, 30A, and 30B are diagrams illustrating a method of manufacturing a semiconductor memory device according to an embodiment of the present disclosure.

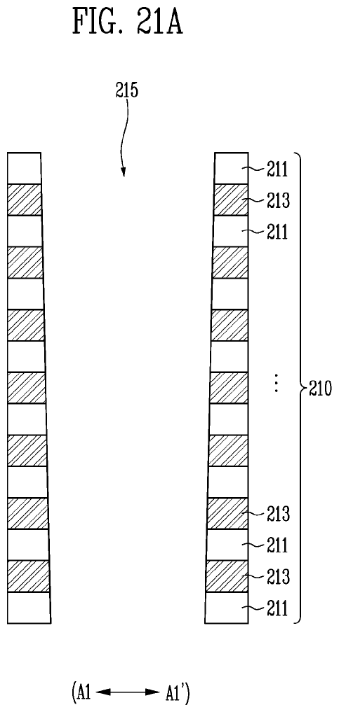

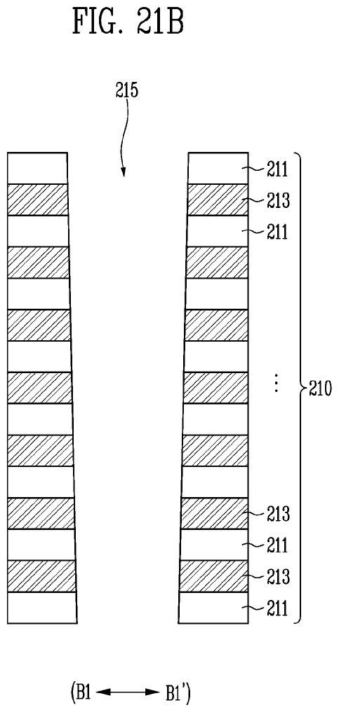

FIGS. 20, 21A, and 21B are diagrams illustrating a process of forming a hole 215 in a preliminary stack 210. FIG. 20 is a plan view of the preliminary stack 210, FIG. 21A is a cross-sectional view of the preliminary stack 210 taken along a line A1-A1′ shown in FIG. 20, and FIG. 21B is a cross-sectional view of the preliminary stack 210 taken along a line B1-B1′ shown in FIG. 20.

Referring to FIGS. 20, 21A, and 21B, the preliminary stack 210 may be formed on a lower structure (not shown). As an embodiment, the lower structure may be a sacrificial substrate formed of a silicon wafer or the like. The sacrificial substrate may be replaced with the doped semiconductor structure DPS described later with reference to FIG. 4B. As another embodiment, the lower structure may be a stack structure including the second structure ST2 and the doped semiconductor structure DPS described with reference to FIG. 4A.

The preliminary stack 210 may be formed on the lower structure according to various embodiments described above. The preliminary stack 210 may include a plurality of first material layers 211 and a plurality of second material layers 213 alternately stacked in the Z-axis direction. Each of the plurality of first material layers 211 and the plurality of second material layers 213 may be formed in a plate shape extending along the plane crossing the Z-axis.

The plurality of second material layers 213 may be formed of a material having an etch selectivity with respect to the plurality of first material layers 211. As an embodiment, the plurality of first material layers 211 may include an insulating material such as a silicon oxide layer and a silicon oxynitride layer, and the plurality of second material layers 213 may include a sacrificial insulating material such as a silicon nitride layer.

Thereafter, the hole 215 may be formed in the preliminary stack 210. Forming the hole 215 may include forming a mask segment (not shown) defining a cross section of the hole 215 on the preliminary stack 210, and etching the plurality of first materials layers 211 and the plurality of second material layers 213 using the mask segment as an etch barrier. The hole 215 may extend in the Z-axis direction to pass through the preliminary stack 210. The cross section of the hole 215 on the plane crossing the Z-axis may be an elliptical shape. A minor axis 215_S of the elliptical shape may face the first direction DR1, and a major axis 215_L of the elliptical shape may face the second direction DR2 or the third direction DR3. The first direction DR1 may be the X-axis direction, the second direction DR2 may be the −Y-axis direction, and the third direction DR3 may be the +Y-axis direction opposite to the second direction DR2. Hereinafter, the Z-axis direction is referred to as the fourth direction DR4.

A case where the cross section of the hole 215 has an elliptical shape may reduce distortion of a shape of the hole 215 and manufacturing process reproducibility of the semiconductor memory device may be improved, compared to a case where the cross section of the hole 215 has a concavo-convex cross section.

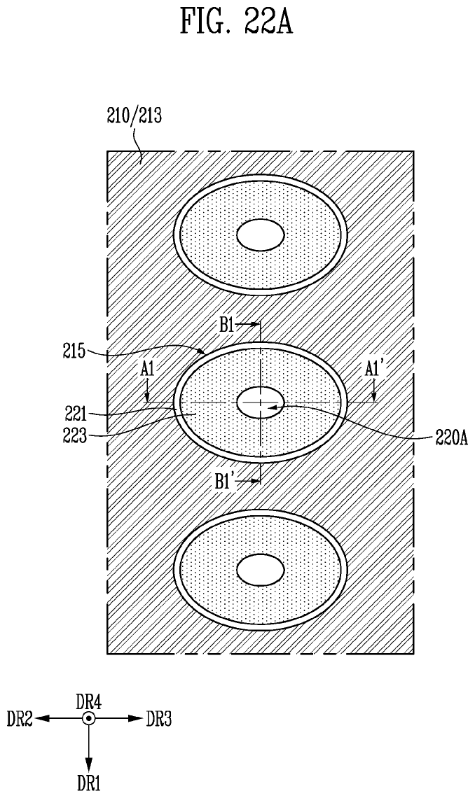

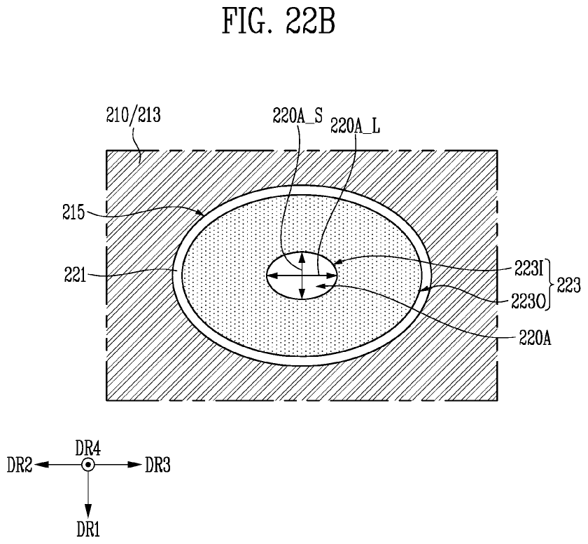

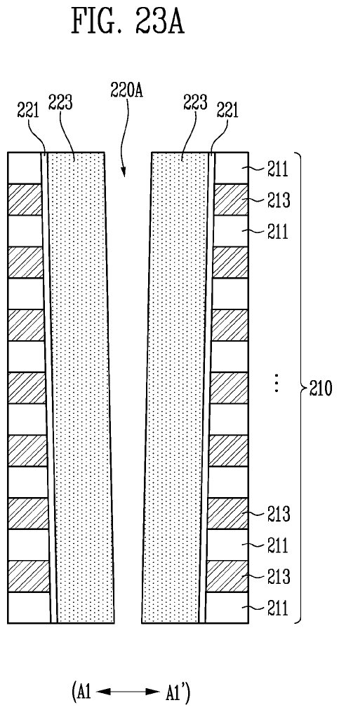

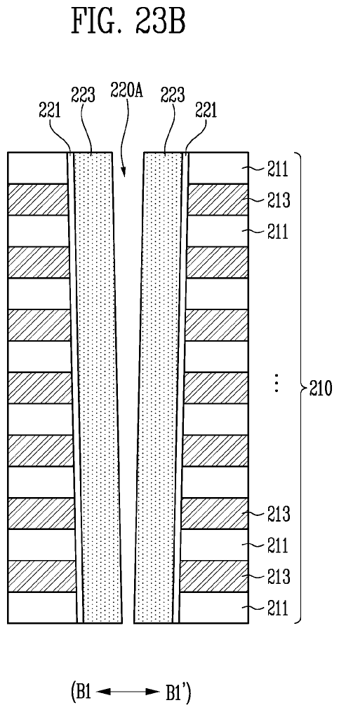

FIGS. 22A, 22B, 23A, and 23B are diagrams illustrating a process of forming a blocking insulating layer 221 and a data storage layer 223 inside the hole 215. FIG. 22A is a plan view of the preliminary stack 210, and FIG. 22B is an enlarged view of a portion of a structure shown in FIG. 22A. FIG. 23A is a cross-sectional view of the preliminary stack 210 taken along a line A1-A1′ shown in FIG. 22A, and FIG. 23B is a cross-sectional view of the preliminary stack 210 taken along a line B1-B1′ shown in FIG. 22A.

Referring to FIGS. 22A and 22B and FIGS. 23A and 23B, the blocking insulating layer 221 may be formed along a side portion of the hole 215. The blocking insulating layer 221 may be formed in various methods. As an embodiment, the blocking insulating layer 221 may be formed by depositing an insulating layer along the side portion of the hole 215. As another embodiment, the blocking insulating layer 221 may be formed by selectively oxidizing a side portion of each of the plurality of second material layers 213 through the hole 215. As still another embodiment, a formation process of the blocking insulating layer 221 may include forming a preliminary layer along a plurality of side portions of the plurality of first materials layers 211 and a plurality of side portions of the plurality of second materials layers 213 exposed through the hole 215, and oxidizing the preliminary layer.

The blocking insulating layer 221 may include a silicon oxide layer, a high dielectric layer. And the like. The high dielectric layer may include an insulating metal oxide layer such as a hafnium oxide layer or an aluminum oxide layer. On the plane, the blocking insulating layer 221 may be formed in a ring shape having a constant width along the hole 215. Accordingly, a cross section of a region opened by the blocking insulating layer 221 may have a reduced area compared to the hole 215, but may be an elliptical shape having a major axis overlapping the major axis 215_L shown in FIG. 20 of the hole 215 and a minor axis overlapping the minor axis 215_S shown in FIG. 20 of the hole 215.

Subsequently, the data storage layer 223 may be formed inside the hole 215. The data storage layer 223 may be formed of various materials like the first data storage segment 123A and the second data storage segment 123B illustrated in FIG. 5. The data storage layer 223 may include an outer portion 2230 and an inner portion 2201. The outer portion 2230 may face the blocking insulating layer 221 or the preliminary stack 210. A first elliptical opening 220A may be defined by the inner portion 2201. On the plane, the data storage layer 223 may be formed in a ring shape having a constant width. Accordingly, a minor axis 220A_S of the first elliptical opening 220A may face the first direction DR1 like the minor axis 215_S of the hole 215 shown in FIG. 20, and may overlap the minor axis 215_S of the hole 215 shown in FIG. 20. In addition, a major axis 220A_L of the first elliptical opening 220A may face the second direction DR2 like the major axis 215_L of the hole 215 shown in FIG. 20, and may overlap the major axis 215_L of the hole 215 shown in FIG. 20.

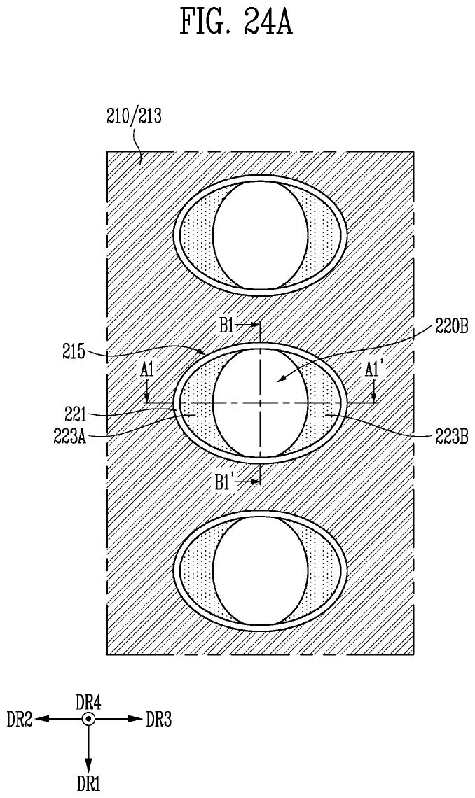

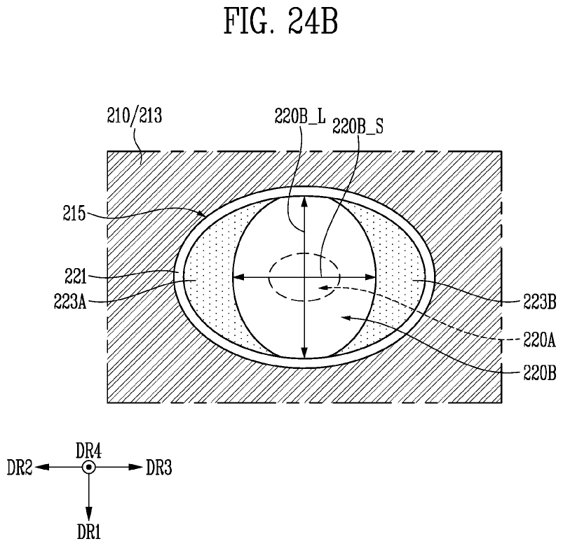

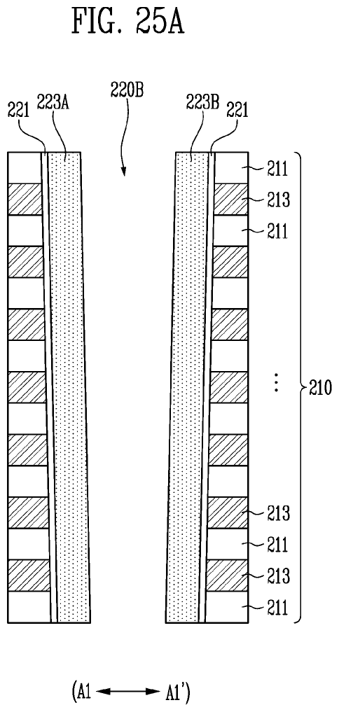

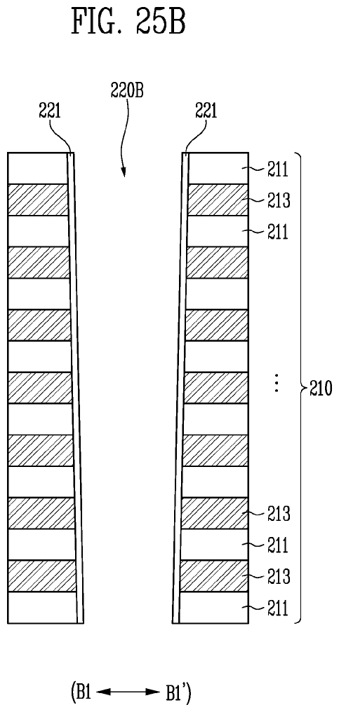

FIGS. 24A, 24B, 25A, and 25B are diagrams illustrating a process of expanding the first elliptical opening 220A into a second elliptical opening 220B. FIG. 24A is a plan view of the preliminary stack 210, and FIG. 24B is an enlarged view of a portion of a structure shown in FIG. 24A. FIG. 25A is a cross-sectional view of the preliminary stack 210 taken along a line A1-A1′ shown in FIG. 24A, and FIG. 25B is a cross-sectional view of the preliminary stack 210 taken along a line B1-B1′ shown in FIG. 24A.

Referring to FIGS. 24A and 24B and FIGS. 25A and 25B, the data storage layer 223 may be isotropically etched from the inner portion 2201 of the data storage layer 223 shown in FIGS. 22A and 22B and FIGS. 23A and 23B through the first elliptical opening 220A. Accordingly, the first elliptical opening 220A may expand into the second elliptical opening 220B.

Isotropic etching may be performed through at least one etching method of wet etching and dry etching. At this time, the areas exposed to an etchant in the inner portion 2201 of the data storage layer 223 shown in FIG. 22B may be different for each region due to a shape of the first elliptical opening 220A. Therefore, an etching rate from the inner portion 2201 to the outer portion 2200 of the data storage layer 223 shown in FIG. 22B may increase near a minor axis 220A_S of FIG. 22B of the first elliptical opening 220A.

The second elliptical opening 220B having a major axis 220B_L facing the first direction DR1 and a minor axis 220B_S facing the second direction DR2 may be formed using the above-described isotropic etching. A portion of the blocking insulating layer 221 may be exposed by the second elliptical opening 220B, and the data storage layer 223 shown in FIGS. 22A and 22B and 23A and 23B may be separated into a first data storage segment 223A and a second data storage segment 223B. The first data storage segment 223A and the second data storage segment 223B may be adjacent to each other in the second direction DR2.

Due to a difference in etching rate for each region of the data storage layer due to a shape of the first elliptical opening 220A, a width of each of the first data storage segment 223A and the second data storage segment 223B may become narrower as each of the first data storage segment 223A and the second data storage segment 223B is adjacent to the major axis 220B_L of the second elliptical opening 223B.

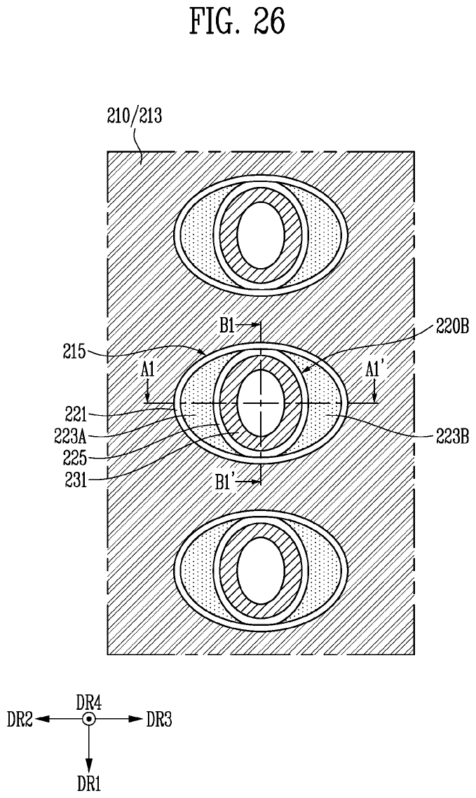

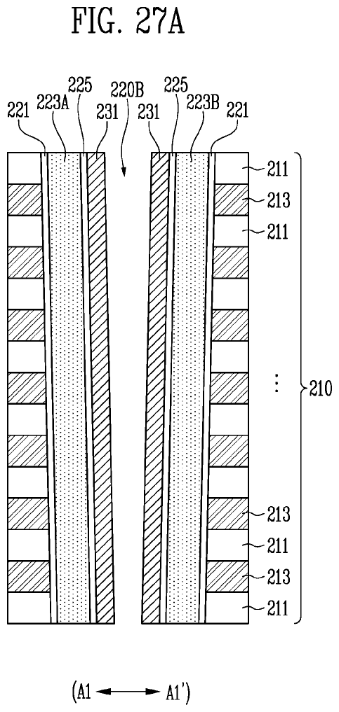

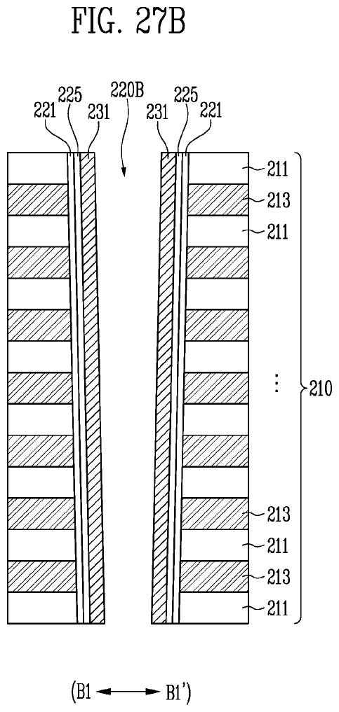

FIGS. 26, 27A, and 27B are diagrams illustrating a process of forming a tunnel insulating layer 225 and the channel layer 231. FIG. 26 is a plan view of the preliminary stack 210, FIG. 27A is a cross-sectional view of the preliminary stack 210 taken along a line A1-A1′ shown in FIG. 26, and FIG. 27B is a cross-sectional view of the preliminary stack 210 taken along a line B1-B1′ shown in FIG. 26.

Referring to FIGS. 26, 27A, and 27B, the tunnel insulating layer 225 may be formed along a side portion of the second elliptical opening 220B. The tunnel insulating layer 225 may be formed in various methods. As an embodiment, the tunnel insulating layer 225 may be formed by depositing an insulating material such as a silicon oxide layer along the side portion of the second elliptical opening 220B. As another example, the tunnel insulating layer 225 may be formed by oxidizing a portion of each of the first data storage segment 223A and the second data storage segment 223B exposed through the second elliptical opening 220B. As still another embodiment, a formation process of the tunnel insulating layer 225 may include forming a preliminary layer along the side portion of the second elliptical opening 220B and oxidizing the preliminary layer.

Subsequently, the channel layer 231 may be formed inside the second elliptical opening 220B. The channel layer 231 may be formed along a side portion of the tunnel insulating layer 225. The channel layer 231 may include silicon (Si), germanium (Ge), or a mixture thereof.

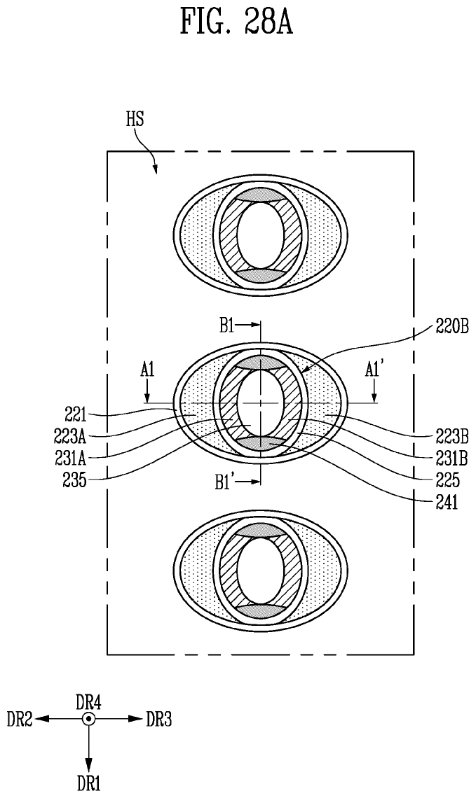

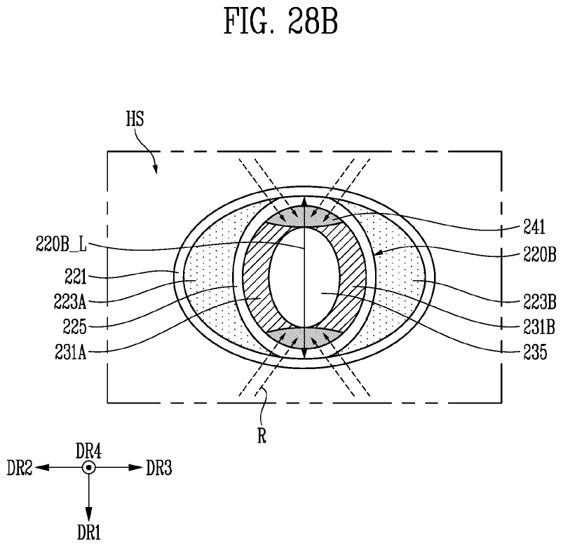

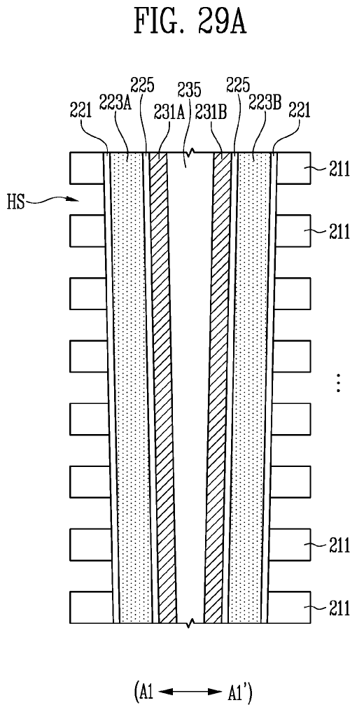

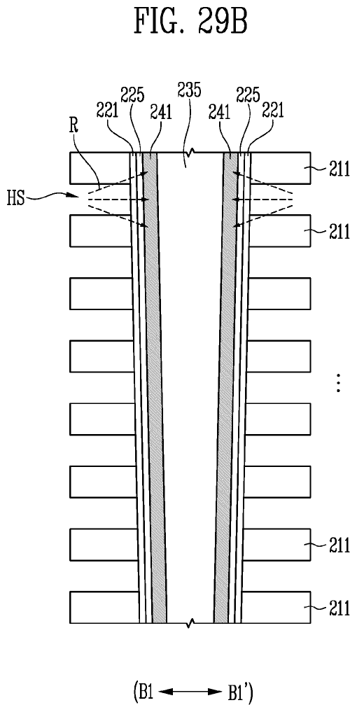

FIGS. 28A, 28B, 29A, and 29B are diagrams illustrating an embodiment of a process following forming the channel layer. FIG. 28A is a plan view of a process result, and FIG. 28B is an enlarged view of a portion of a structure shown in FIG. 28A. FIG. 29A is a cross-sectional view of a process result taken along a line A1-A1′ shown in FIG. 28A, and FIG. 29B is a cross-sectional view of a process result taken along a line B1-B1′ shown in FIG. 28A.

Referring to FIGS. 28A and 28B and 29A and 29B, an insulating pillar 235 may be formed inside the second elliptical opening 220B opened by the channel layer 231 shown in FIGS. 26, 27A, and 27B. The insulating pillar 235 may be formed by filling a central region of the second elliptical opening 220B with an insulating material.

Subsequently, the slit SI as described with reference to FIG. 5 may be formed, and the plurality of second material layers 213 shown in FIGS. 26, 27A, and 27B may be removed through the slit SI. Accordingly, a horizontal space HS may be opened between the first material layers 211 adjacent in the fourth direction DR4.

Thereafter, a portion of the channel layer 231 shown in FIGS. 26 and 27B may be selectively oxidized through the horizontal space HS. Selective oxidation may be performed through a wet oxidation process. At this time, the first data storage segment 223A and the second data storage segment 223B may be hardly oxidized and may serve as a barrier of the wet oxidation process. Accordingly, another portion of the channel layer 231 protected by the first data storage segment 223A and the second data storage segment 223B may remain as a first channel segment 231A and a second channel segment 231B. An oxidation region of the channel layer 231 may form a channel separation structure 241. The channel separation structure 241 may be formed by selectively oxidizing a portion of the channel layer 231 adjacent to the major axis 220B_L of the second elliptical opening 220B by a wet oxidation method performed through a path R indicated by a dotted line.

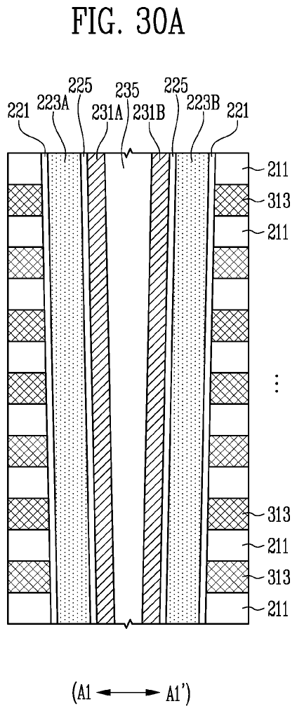

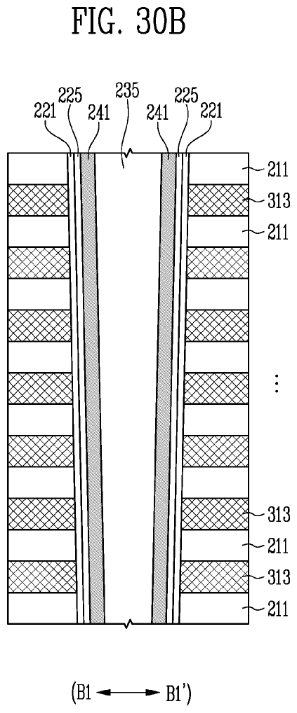

FIGS. 30A and 30B are diagrams illustrating a formation process of a plurality of third material layers 313. FIG. 30A is a cross-sectional view illustrating the plurality of third material layers 313 in the same direction as in FIG. 29A, and FIG. 30B is a cross-sectional view illustrating the plurality of third material layers 313 in the same direction as in FIG. 29B.

Referring to FIGS. 30A and 30B, a third material layer 313 may be formed inside the horizontal space HS shown in FIGS. 29A and 29B. The third material layer 313 may include at least one of a doped semiconductor layer, a metal layer, and a conductive metal nitride layer.

The semiconductor memory device shown in FIGS. 5 to 7B may be formed using the processes described above with reference to FIGS. 20 to 30B.

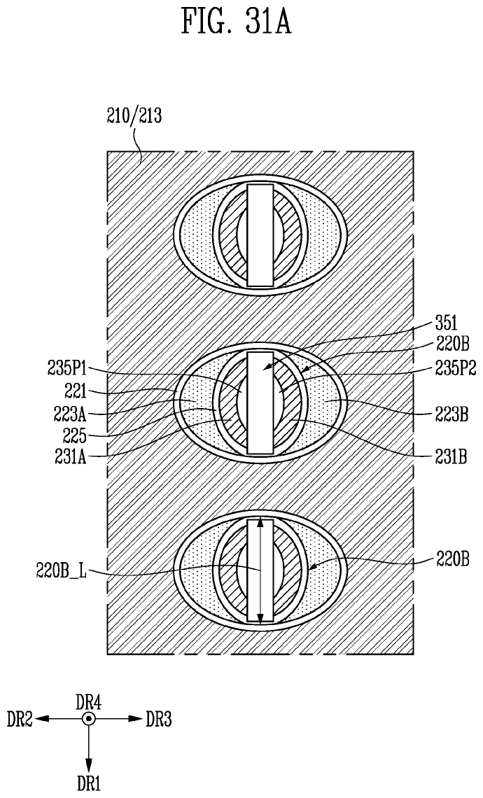

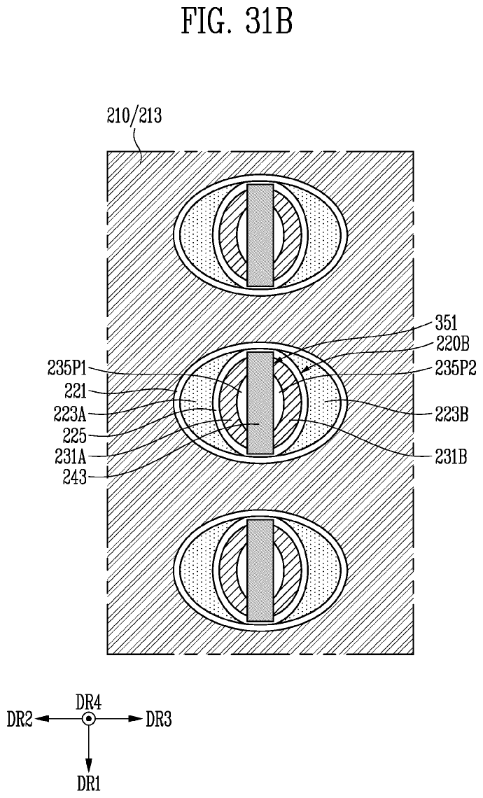

FIGS. 31A and 31B are plan views illustrating a method of manufacturing a semiconductor memory device according to an embodiment of the present disclosure.

Hereinafter, an overlapping description for the same processes as those in FIGS. 20 to 30B is simplified or omitted.

Prior to performing a process shown in FIG. 31A, the processes described with reference to FIGS. 20 to 27B may be performed. Accordingly, as shown in FIGS. 26, 27A, and 27B, the preliminary stack 210 including the plurality of first material layers 211 and the plurality of second material layers 213 penetrated by the hole 215 and alternately stacked may be provided. In addition, the tunnel insulating layer 225, the first data storage segment 223A, the second data storage segment 223B, the tunnel insulating layer 225, and the channel layer 231 may be formed inside the hole 215. A central region of the second elliptical opening 220B may be opened by the channel layer 231 having a ring shape of planar structure. Thereafter, as shown in FIGS. 28A to 29B, the insulating pillar 235 may be formed inside the second elliptical opening 220B. Subsequently, a trench for separating the channel layer 231 into a first channel segment and a second channel segment may be formed.

As an embodiment, as shown in FIG. 31A, the channel layer may be separated into the first channel segment 231A and the second channel segment 231B by forming a trench 351 to pass through the channel layer and the insulating pillar.

Referring to FIG. 31A, the trench 351 may be formed by removing a portion of the insulating pillar and a portion of the channel layer. The insulating pillar may be separated into a first convex portion 235P1 adjacent to the first data storage segment 223A and a second convex portion 235P2 adjacent to the second data storage segment 223B by the trench 351. The channel layer may be separated into the first channel segment 231A adjacent to the first data storage segment 223A and the second channel segment 231B adjacent to the second data storage segment 223B by the trench 351.

Forming the trench 351 may include forming a mask segment (not shown) defining a cross section of the trench 351 on the preliminary stack 210, and etching a portion of the insulating pillar adjacent to the major axis 220B_L of 220B of the second elliptical opening 220B and a portion of the channel layer adjacent to the major axis 220B_L of the second elliptical opening 220B using the mask segment as an etch barrier. The trench 351 may overlap the major axis 220B_L of the second elliptical opening 220B. As an embodiment, a length of the trench 351 in the first direction DR1 may be controlled so that the trench 351 passes through the insulating pillar and the channel layer. As another embodiment, the length of the trench 351 in the first direction DR1 may be controlled so that the trench 351 passes through the insulating pillar, the channel layer, and the tunnel insulating layer 225. As still another embodiment, the length of the trench 351 in the first direction DR1 may be controlled so that the trench 351 passes through the insulating pillar, the channel layer, the tunnel insulating layer 225 and the blocking insulating layer 221.

Referring to FIG. 31B, the trench 351 may be filled with an insulating material. Accordingly, the insulating segment 243 may be formed inside the trench 351.

After forming the insulating segment 243, the slit SI as described with reference to FIG. 5 may be formed. The second material layer 213 shown in FIGS. 31A and 31B may be formed of a sacrificial insulating material as described with reference to FIGS. 20 to 21B. At this time, the second material layer 213 may be replaced with the third material layer described with reference to FIGS. 30A and 30B through the slit.

The semiconductor memory device shown in FIGS. 8 to 9B may be formed using the processes described above with reference to FIGS. 31A and 31B.

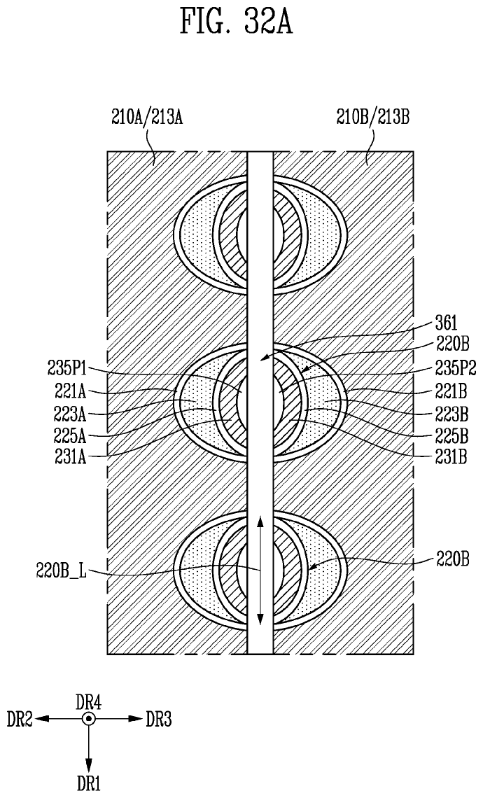

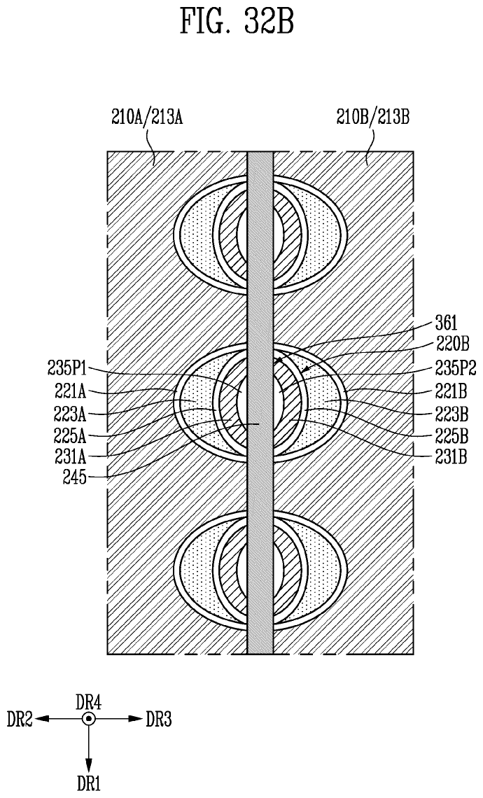

FIGS. 32A and 32B are plan views illustrating a method of manufacturing a semiconductor memory device according to an embodiment of the present disclosure.

FIG. 32A is a diagram illustrating another embodiment of a formation process of the trench. Referring to FIG. 32A, a trench 361 may be formed to pass through a partial region of the preliminary stack 210 shown in FIGS. 26 to 27B in addition to the channel layer and the insulating pillar. Accordingly, the channel layer may be separated into the first channel segment 231A and the second channel segment 231B.

The trench 361 may overlap the major axis 220B_L of the second elliptical opening 220B and may extend in the first direction DR1 to pass through the blocking insulating layer and the preliminary stack. Accordingly, the insulating pillar may be separated into the first convex portion 235P1 adjacent to the first data storage segment 223A and the second convex portion 235P2 adjacent to the second data storage segment 223B by the trench 361. The channel layer may be separated into the first channel segment 231A adjacent to the first data storage segment 223A and the second channel segment 231B adjacent to the second data storage segment 223B by the trench 361. The tunnel insulating layer may be separated into a first tunnel insulating segment 225A adjacent to the first data storage segment 223A and a second tunnel insulating segment 225B adjacent to the second data storage segment 223B by the trench 361. The blocking insulating layer may be separated into a first blocking insulating segment 221A adjacent to the first data storage segment 223A and a second blocking insulating segment 221B adjacent to the second data storage segment 223B by the trench 361. The preliminary stack may be separated into a first stack 210A and a second stack 210B by the trench 361.

Hereinafter, a plurality of second material layers of the first stack 210A are referred to as a first group of second material layers 213A, and a plurality of second material layers of the second stack 210B are referred to as a second group of second material layer 213B. The first group of second material layer 213A may be separated from the second group of second material layer 213B by the trench 361.

Referring to FIG. 32B, the trench 361 shown in FIG. 32A may be filled with an insulating material. Accordingly, an insulating segment 245 may be formed inside the trench 361 shown in FIG. 32A.

After forming the insulating segment 245, the slit SI as described with reference to FIG. 5 may be formed to pass through the first stack 210A and the second stack 210B. The first group of second material layer 213A and the second group of second material layer 213B shown in FIGS. 32A and 32B may be formed of a sacrificial insulating material like the second material layer described with reference to FIGS. 20 to 21B. At this time, each of the first group of second material layer 213A and the second group of second material layer 213B may be replaced with the third material layer described with reference to FIGS. 30A and 30B through the slit.

The semiconductor memory device gate stack shown in FIGS. 11 to 12B may be formed using the processes described above with reference to FIGS. 32A and 32B.

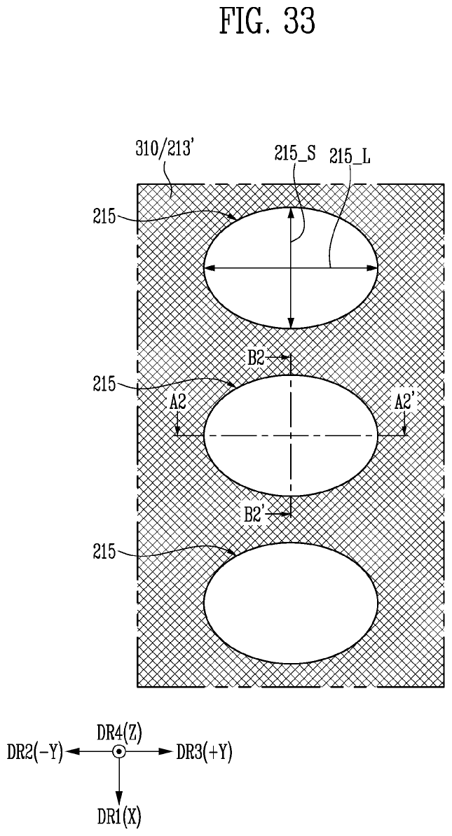

FIGS. 33, 34A, 34B, 35, and 36 are diagrams illustrating a method of manufacturing a semiconductor memory device according to an embodiment of the present disclosure.

Hereinafter, an overlapping description of the same processes as those in FIGS. 20 to 30B is simplified or omitted.

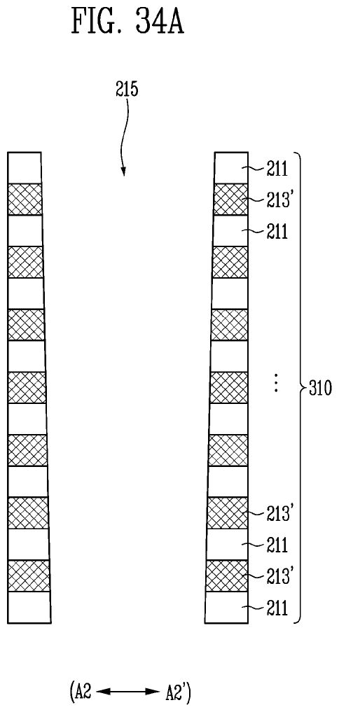

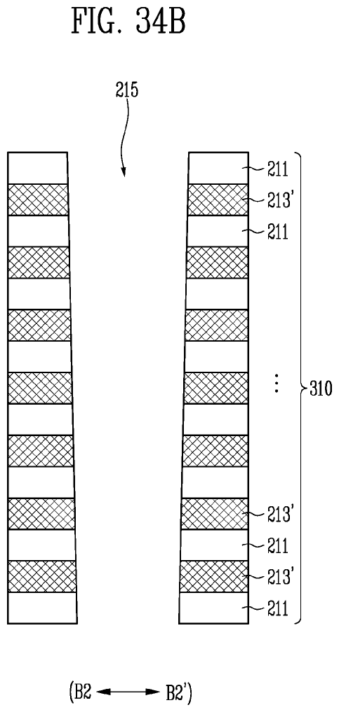

FIGS. 33, 34A, and 34B are diagrams illustrating a process of forming the hole 215 in a preliminary stack 310. FIG. 33 is a plan view of the preliminary stack 310, FIG. 34A is a cross-sectional view of the preliminary stack 310 taken along a line A2-A2′ shown in FIG. 33, and FIG. 34B is a cross-sectional view of the preliminary stack 310 taken along a line B2-B2′.

Referring to FIGS. 33, 34A, and 34B, as described with reference to FIGS. 20 to 21B, the preliminary stack 310 may be formed on the lower structure (not shown). The preliminary stack 310 may include a plurality of first material layers 211 and a plurality of second material layers 213′ alternately stacked in the Z-axis direction. Each of the plurality of first material layers 211 and the plurality of second material layers 213′ may be formed in a plate shape extending along the plane crossing the Z-axis. The plurality of first material layers 211 may include an insulating material such as a silicon oxide layer or a silicon oxynitride layer, and the plurality of second material layers 213′ may be formed of the conductive material identical to that of the third material layer described with reference to FIGS. 30A and 30B.

Subsequently, as described with reference to FIGS. 20 to 21B, the hole 215 may be formed in the preliminary stack 310. The hole 215 may extend in the Z-axis direction to pass through the preliminary stack 310. A cross section of the hole 215 may be an elliptical shape on the plane crossing the Z-axis. The minor axis 215_S of the elliptical shape may face the first direction DR1, and the major axis 215_L of the elliptical shape may face the second direction DR2 or the third direction DR3. The first direction DR1 may be the X-axis direction, the second direction DR2 may be the −Y-axis direction, and the third direction DR3 may be the +Y-axis direction opposite to the second direction DR2. The Z-axis direction may be the fourth direction DR4.

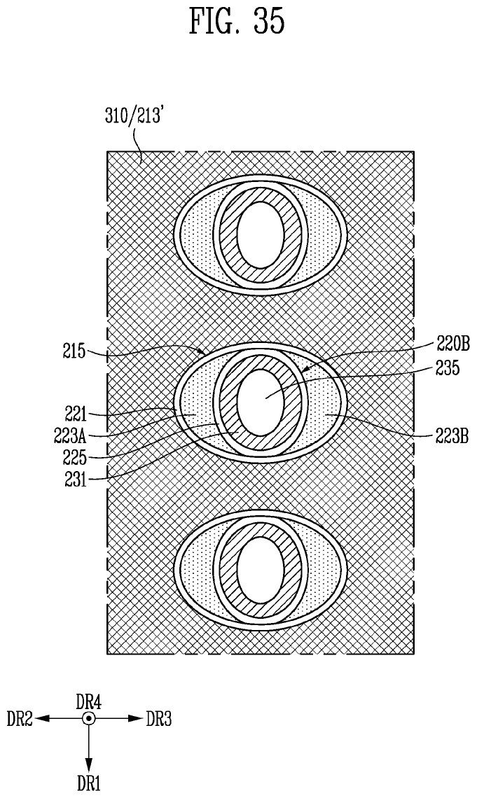

FIG. 35 is a plan view illustrating a process performed inside the hole 215.

Referring to FIG. 35, the blocking insulating layer 221, the first data storage segment 223A, and the second data storage segment 223B may be formed inside the hole 215 using the processes described with reference to FIGS. 22A to 25B. The first data storage segment 223A and the second data storage segment 223B may be separated from each other by the second elliptical opening 220B as described with reference to FIGS. 22A to 23B.

Subsequently, as described with reference to FIGS. 26 to 27B, the tunnel insulating layer 225 and the channel layer 231 may be formed inside the second elliptical opening 220B. A central region of the second elliptical opening 220B may be opened by the channel layer 231 having a ring shape of planar structure. Thereafter, the insulating pillar 235 may be formed inside the second elliptical opening 220B.

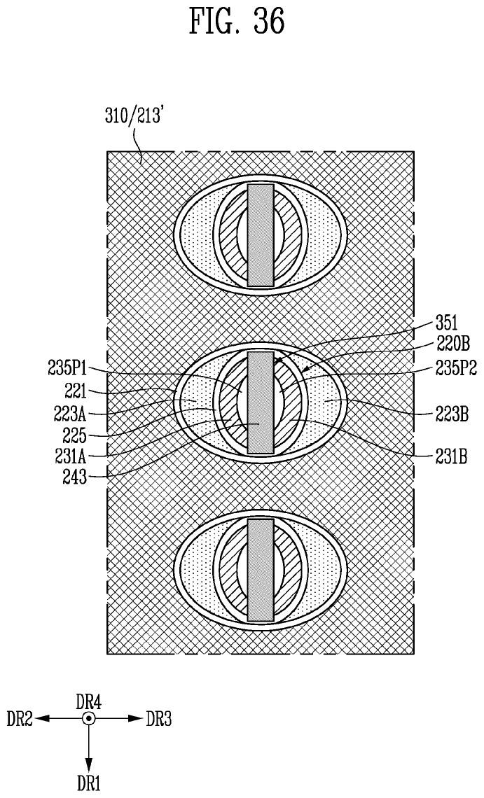

FIG. 36 is a plan view illustrating a process of separating the channel layer 231 shown in FIG. 35 into the first channel segment 231A and the second channel segment 231B.

Referring to FIG. 36, the trench 351 passing through the channel layer 231 and the insulating pillar 235 shown in FIG. 35 may be formed using the process described with reference to FIG. 31A, and the insulating segment 243 may be formed inside the trench 351 using the process described with reference to FIG. 31B. Accordingly, the insulating pillar may be separated into the first convex portion 235P1 adjacent to the first data storage segment 223A and the second convex portion 235P2 adjacent to the second data storage segment 223B. The channel layer may be separated into the first channel segment 231A adjacent to the first data storage segment 223A and the second channel segment 231B adjacent to the second data storage segment 223B.

Thereafter, the preliminary stack 310 may be penetrated by the slit SI as described with reference to FIG. 5. Accordingly, the preliminary stack 310 may be partitioned in a gate stack unit. The second material layer 213′ of the preliminary stack 310 may be used as a gate electrode that controls the first channel segment 231A and the second channel segment 231B.

The semiconductor memory device gate stack shown in FIGS. 8 to 9B may be formed using the processes described above with reference to FIGS. 33 to 36.

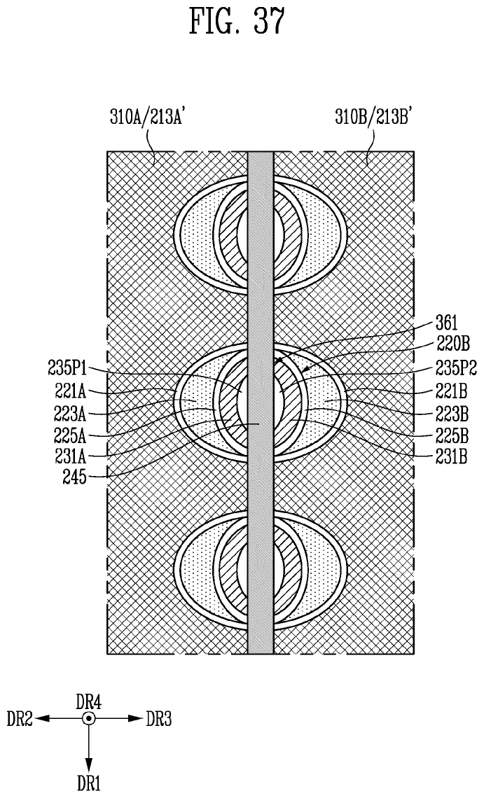

FIG. 37 is a plan view illustrating a method of manufacturing a semiconductor memory device according to an embodiment of the present disclosure.

Steps of a process of making the gate stack shown in FIG. 37, are shown in FIGS. 33 to 34B. A preliminary stack 310 including the plurality of first material layers 211 and the plurality of second material layers 213′ are alternately stacked and the hole 215 passing through the preliminary stack 310 may be formed. Subsequently, as shown in FIG. 35, the blocking insulating layer 221, the first data storage segment 223A, the second data storage segment 223B, the tunnel insulating layer 225, the channel layer 231, and the insulating pillar 235 may be formed inside the hole 215. The first data storage segment 223A and the second data storage segment 223B may be separated from each other by the second elliptical opening 220B as described with reference to FIGS. 22A to 23B.

Referring to FIG. 37, a trench 361 passing through the channel layer 231 and the insulating pillar 235 shown in FIG. 35 may be formed using the process described with reference to FIG. 32A. The insulating segment 245 may be formed inside the trench 361 using the process described with reference to FIG. 32B. Accordingly, the insulating pillar may be separated into the first convex portion 235P1 adjacent to the first data storage segment 223A and the second convex portion 235P2 adjacent to the second data storage segment 223B. The channel layer may be separated into the first channel segment 231A adjacent to the first data storage segment 223A and the second channel segment 231B adjacent to the second data storage segment 223B. In addition, the tunnel insulating layer may be separated into the first tunnel insulating segment 225A adjacent to the first data storage segment 223A and the second tunnel insulating segment 225B adjacent to the second data storage segment 223B. The blocking insulating layer 221 may be separated into the first blocking insulating segment 221A adjacent to the first data storage segment 223A and the second blocking insulating segment 221B adjacent to the second data storage segment 223B.

The preliminary stack may be separated into a first stack 310A and a second stack 310B by the trench 361 and the insulating segment 245. The plurality of second material layers of the first stack 310A may be used as the plurality of first conductive layers 213A′, and the plurality of second material layers of the second stack 310B may be used as a plurality of second conductive layers 213B′. Thereafter, the plurality of first conductive layers 213A′ and the plurality of second conductive layers 213B may be partitioned in a gate stack unit by forming slits SI as described with reference to FIG. 5. Each of the first conductive layers 213A′ may be used as a gate electrode that controls the first channel segment 231A, and each of the second conductive layers 213B′ may be used as a gate electrode that controls the second channel segment 231B.

The semiconductor memory device gate stack shown in FIGS. 11 to 12B may be formed using the processes described above with reference to FIG. 37.

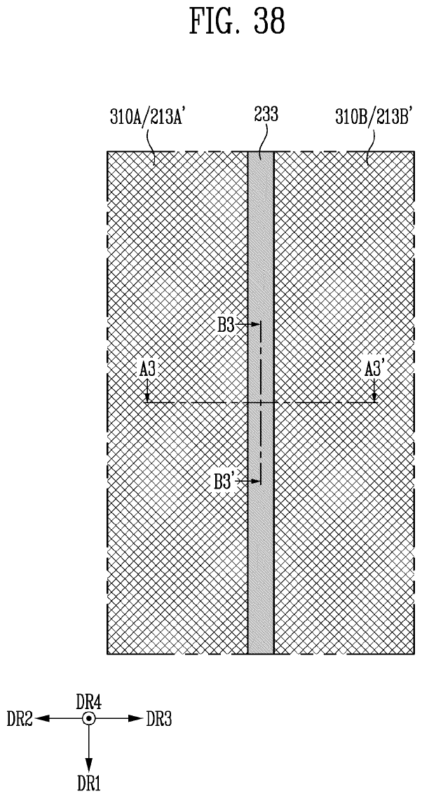

FIGS. 38, 39A, 39B, 40, 41A, 41B, and 42 are diagrams illustrating a method of manufacturing a semiconductor memory device according to an embodiment of the present disclosure.

Hereinafter, an overlapping description of the same processes as those in FIGS. 20 to 30B is simplified or omitted.

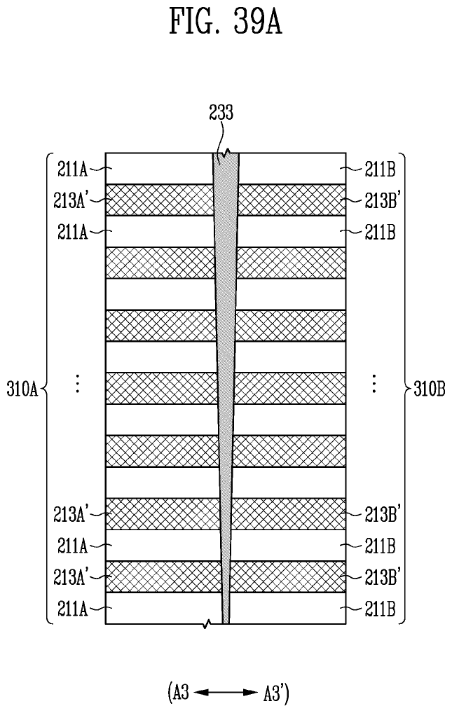

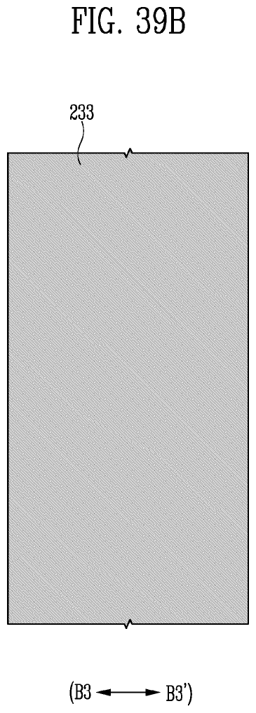

FIGS. 38, 39A, and 39B are diagrams illustrating a process of forming the first stack 310A and the second stack 310B separated by a gate separation structure 233. FIG. 38 is a plan view illustrating a layout of the first stack 310A, the second stack 310B, and the gate separation structure 233. FIG. 39A is a cross-sectional view of the first stack 310A and the second stack 310B taken along a line A3-A3′ shown in FIG. 38, and FIG. 39B is a cross-sectional view of the gate separation structure 233 taken along a line B3-B3′ shown in FIG. 38.

Referring to FIGS. 38 to 39B, the plurality of first material layers 211 and the plurality of second material layers 213′ shown in FIGS. 33 to 34B may be alternately stacked on the lower structure (not shown) described with reference to FIGS. 20 to 21B. Subsequently, the gate separation structure 233 passing through the plurality of first material layers 211 and the plurality of second material layers 213′ shown in FIGS. 33 to 34B may be formed. The gate separation structure 233 may extend in the first direction DR1 on the plane. The plurality of first material layers 211 and the plurality of second material layers 213′ shown in FIGS. 33 to 34B may be separated into the first stack 310A and the second stack 310B by the gate separation structure 233.

Hereinafter, a plurality of first material layers of the first stack 310A are referred to as a first group of first material layers 211A, and the plurality of second material layers of the second stack 310B are referred to as a second group of first material layer 211B. In addition, a plurality of second material layers of the first stack 310A are referred to as a first conductive layer 213A′, and a plurality of second material layers of the second stack 310B are referred to as a second conductive layers 213B′.

The first group of first material layer 211A and the first conductive layer 213A′ may extend in the second direction DR2 from the gate separation structure 233. The second group of first material layer 211B and the second conductive layer 213B′ may extend in the third direction DR3, which is opposite to the second direction DR2, from the gate separation structure 233. The gate separation structure 233 may extend in the fourth direction DR4 to be located between the first conductive layer 213A′ and the second conductive layer 213B′ from between the first group of first material layer 211A and the second group of first material layer 211B.

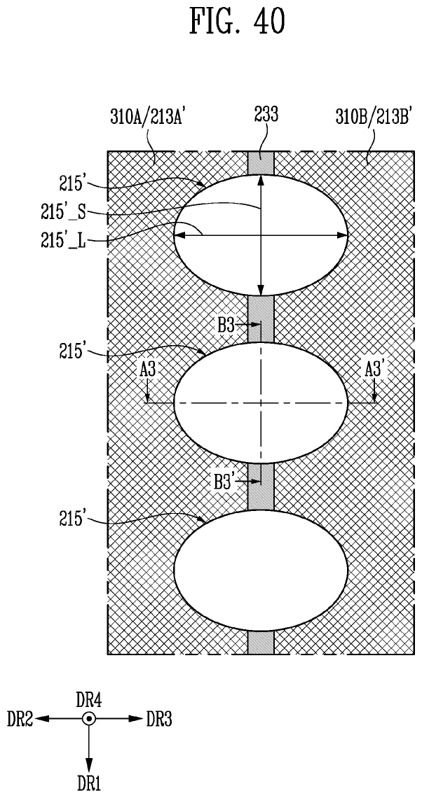

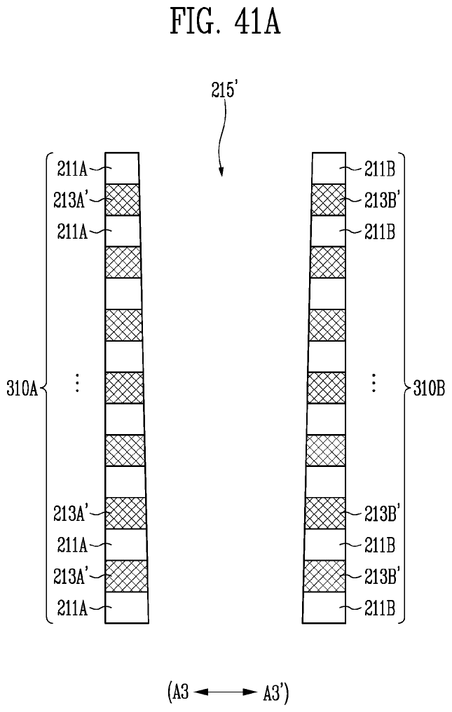

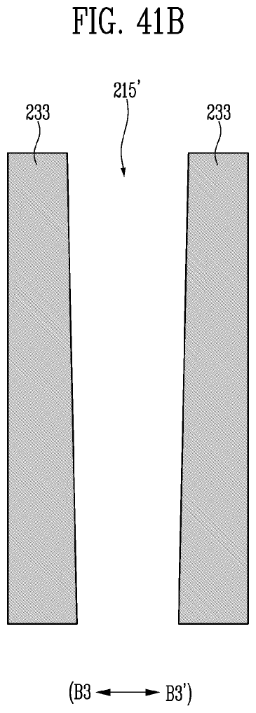

FIGS. 40, 41A, and 41B are diagrams illustrating a formation process of a hole 215′. FIG. 40 is a plan view illustrating a formation process of the hole 215′, FIG. 41A is a cross-sectional view of the hole 215′ taken along a line A3-A3′ shown in FIG. 40, and FIG. 41B is a cross-sectional view of the hole 215′ taken along a line B3-B3′.

Referring to FIGS. 40, 41A, and 41B, the hole 215′ extending in the fourth direction DR4 may be formed to pass through the gate separation structure 233. The hole 215′ may extend into the first stack 310A and the second stack 310B on both sides of the gate separation structure 233.

As the hole 215 shown in FIGS. 20 to 21B, in a plan view, a cross section of the hole 215′ may be an elliptical shape. A minor axis 215′_S of the elliptical shape may face the first direction DR1, and a major axis 215′_L of the elliptical shape may face the second direction DR2 or the third direction DR3.

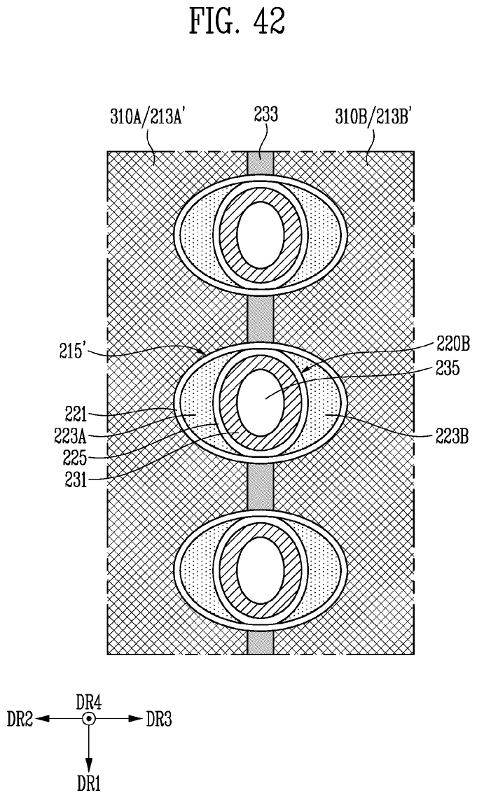

FIG. 42 is another plan view of a gate stack, which may also aid in the description of its formation.

Referring to FIG. 42, the blocking insulating layer 221, the first data storage segment 223A, and the second data storage segment 223B may be formed inside the hole 215′ using the processes described with reference to FIGS. 22A to 25B. The first data storage segment 223A and the second data storage segment 223B may be separated from each other by the second elliptical opening 220B as described with reference to FIGS. 22A to 23B.

Subsequently, as described with reference to FIGS. 26 to 27B, the tunnel insulating layer 225 and the channel layer 231 may be formed inside the second elliptical opening 220B. A central region of the second elliptical opening 220B may be opened by the channel layer 231 having a ring shape of planar structure. Thereafter, the insulating pillar 235 may be formed inside the second elliptical opening 220B. The channel layer 231 may include a first channel region of a first memory cell string controlled by the first conductive layer 213A′ and a second channel region of a second memory cell string controlled by the second conductive layer 213B′.

The semiconductor memory device and its gate stack shown in FIGS. 17 to 19B may be formed using the processes described above with reference to FIGS. 38 to 42.

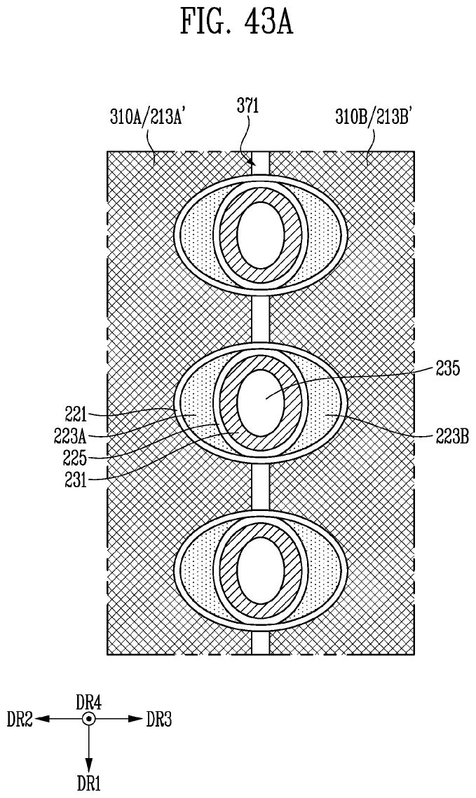

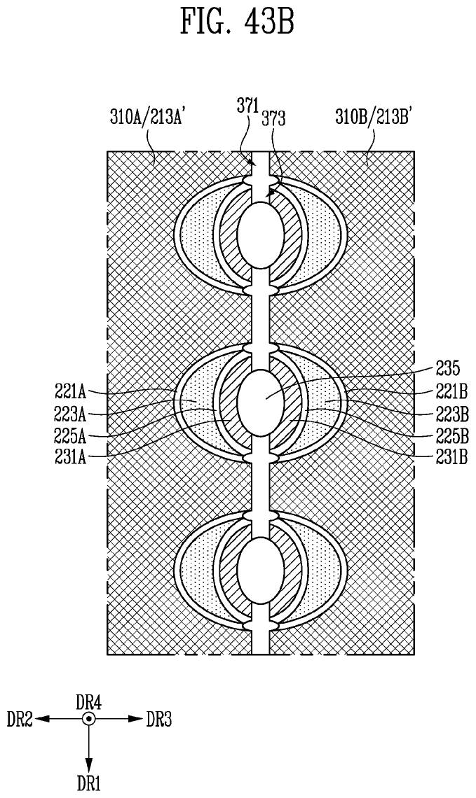

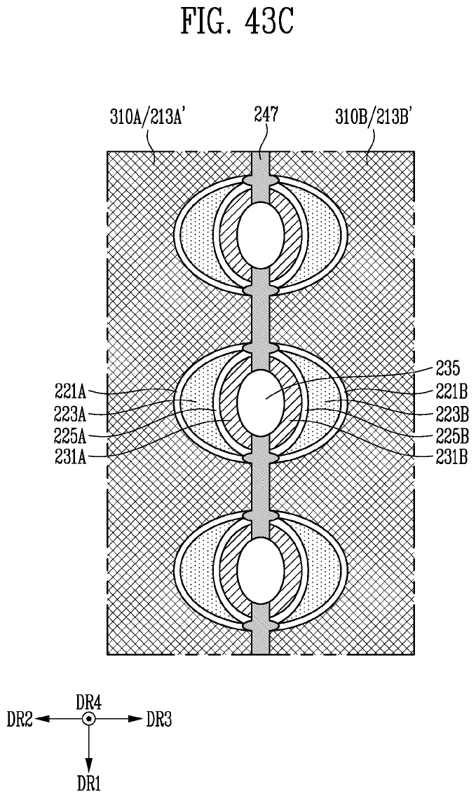

FIGS. 43A, 43B, and 43C are plan views illustrating a method of manufacturing a semiconductor memory device according to an embodiment of the present disclosure.

Prior to performing a process shown in FIG. 43A, the processes described with reference to FIGS. 38 to 42 may be performed. Accordingly, a gate stack structure as shown in FIG. 42 may be provided.

Referring to FIG. 43A, the gate separation structure 233 shown in FIG. 42 may be removed. Accordingly, an opening 371 exposing the blocking insulating layer 221 may be defined between the first stack 310A and the second stack 310B.

Referring to FIG. 43B, a recess portion 373 may be formed by removing a portion of the blocking insulating layer 221 shown in FIG. 43A, a portion of the tunnel insulating layer 225 shown in FIG. 43A, and a portion of the channel layer 231 shown in FIG. 43A through the opening 371. The insulating pillar 235 may be exposed by the recess portion 373.

The blocking insulating layer may be separated into the first blocking insulating segment 221A and the second blocking insulating segment 221B by the recess portion 373. The tunnel insulating layer may be separated into the first tunnel insulating segment 225A and the second tunnel insulating segment 225B by the recess portion 373. The channel layer may be separated into the first channel segment 231A and the second channel segment 231B by the recess portion 373.

Referring to FIG. 43C, the opening 371 and the recess portion 373 shown in FIG. 43B may be filled with an insulating segment 247. The first conductive layer 213A′ and the second conductive layer 213B′ separated from each other with the insulating segment 247 and the insulating pillar 235 located therebetween may individually control the first channel segment 231A and the second channel segment 231B.

The semiconductor memory device gate stack shown in FIGS. 13 to 14B may be formed using the processes described above with reference to FIGS. 43A to 43C.

Each of the second material layer of the first stack 310A and the second material layer of the second stack 310B shown in FIG. 43A may be formed of a sacrificial insulating material like the second material layer described with reference to FIGS. 20 to 21B. At this time, the second material layer of the first stack 310A and the second material layer of the second stack 310B may be replaced with the third material layer described with reference to FIGS. 30A and 30B through the slit SI as shown in FIG. 5.

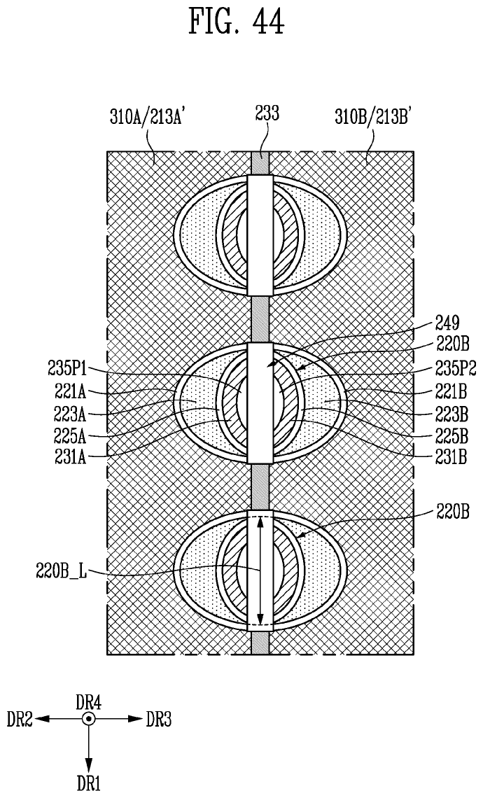

FIG. 44 is a plan view illustrating a method of manufacturing a semiconductor memory device according to an embodiment of the present disclosure.

FIG. 44 illustrates an embodiment of a process that follows after performing the processes described with reference to FIGS. 38 to 42.

Referring to FIG. 44, a recess portion 249 passing through the insulating pillar 235 shown in FIG. 42 and exposing a side portion of the gate separation structure 233 may be formed. The recess portion 249 may be formed by removing a portion of the insulating pillar overlapping the major axis 220B_L of the second elliptical opening 220B, a portion of the tunnel insulating layer overlapping the major axis 220B_L of the second elliptical opening 220B, and a portion of the blocking insulating layer overlapping the major axis 220B_L of the second elliptical opening 220B through an etching process.

The blocking insulating layer may be separated into the first blocking insulating segment 221A and the second blocking insulating segment 221B by the recess portion 249. The tunnel insulating layer may be separated into the first tunnel insulating segment 225A and the second tunnel insulating segment 225B by the recess portion 249. The channel layer may be separated into the first channel segment 231A and the second channel segment 231B by the recess portion 249.

The first conductive layer 213A′ and the second conductive layer 213B′ separated from each other with the recess portion 249 and the gate separation structure 233 located therebetween may individually control the first channel segment 231A and the second channel segment 231B.

Thereafter, the recess portion 249 may be filled with the insulating segment 149 as shown in FIG. 15.

The semiconductor memory device shown in FIGS. 15 to 16B may be formed using the processes described above with reference to FIG. 44.

Each of the second material layer of the first stack 310A and the second material layer of the second stack 310B shown in FIG. 44 may be formed of a sacrificial insulating material like the second material layer described with reference to FIGS. 20 to 21B. The second material layer of the first stack 310A and the second material layer of the second stack 310B may be replaced with the third material layer described with reference to FIGS. 30A and 30B through the slit SI as shown in FIG. 5.

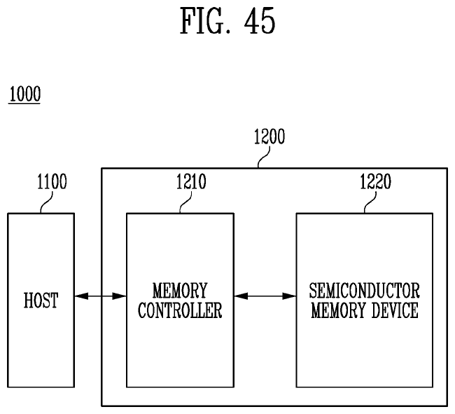

FIG. 45 is a block diagram illustrating an electronic system including a semiconductor memory device according to embodiments of the present disclosure.

Referring to FIG. 45, the electronic system 1000 may be a computing system, a medical device, a communication device, a wearable device, a memory system, and the like. The electronic system 1000 may include a host 1100 and a storage device 1200.

The host 1100 may store data in the storage device 1200 or read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA interface, a parallel-ATA interface, a small computer system interface (SCSI), an enhanced small disk interface (ESDI), integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220 having a gate stack as described herein. In one embodiment, the storage device 1200 may be a storage medium such as a solid state drive (SSD) or a USB memory.

The memory controller 1210 may store data in the semiconductor memory device 1220 or read data stored in the semiconductor memory device 1220 under control of the host 1100.

The semiconductor memory device 1220 may include one memory chip or a plurality of memory chips. The semiconductor memory device 1220 may store data or output stored data under control of the memory controller 1210.

The semiconductor memory device 1220 may be a nonvolatile memory device. The semiconductor memory device 1220 may include a gate stack including a first concave portion and a second concave portion concave in opposite directions, and a first data storage segment and a second data storage segment individually corresponding to the first concave portion and the second concave portion. Widths of the first data storage segment and the second data storage segment may become narrower toward an end on the plane.

According to various embodiments of the present disclosure, a data storage layer may be separated into a first data storage segment and a second data storage segment by etching the data storage layer inside a hole. Because the first data storage segment and the second data storage segment may be used as individual memory cells, an integration degree of the memory cells may be improved.

What is claimed is:

1. A semiconductor memory device comprising:
a gate stack including a first concave portion and a second concave portion, the first and second concave portions facing opposite directions based on a straight line on a geometric plane;
an insulating pillar having a first convex portion facing the first concave portion of the gate stack and a second convex portion facing the second concave portion of the gate stack;
a first channel segment extending along the first convex portion of the insulating pillar;
a second channel segment extending along the second convex portion of the insulating pillar;
a channel separation structure extending from the insulating pillar to between an end of the first channel segment and an end of the second channel segment;
a first data storage segment located between the first channel segment and the first concave portion of the gate stack; and
a second data storage segment located between the second channel segment and the second concave portion of the gate stack,
wherein a width of each of the first data storage segment and the second data storage segment becomes narrower as each of the first data storage segment and the second data storage segment is close the channel separation structure.

2. The semiconductor memory device of claim 1, wherein an outer convex portion of the first data storage segment faces a first portion of the gate stack,
wherein an outer convex portion of the second data storage segment also faces a second portion of the gate stack, and
wherein the outer convex portions of the first and second data storage segments contact an inner concave portion of elliptically-shaped ring.

3. The semiconductor memory device of claim 1, wherein each of the first channel segment and the second channel segment comprises:
an inner concave portion facing the insulating pillar; and
an outer convex portion facing the gate stack, and
wherein a curvature of the outer convex portion is substantially the same as a curvature of the inner concave portion.

4. The semiconductor memory device of claim 1, further comprising:
a blocking insulating layer located between outside surfaces of the first and second data storage segments and the gate stack; and
a tunnel insulating layer extending along outer convex-shaped surfaces of the first and second channel segments, the outer convex-shaped surfaces facing the gate stack.

5. The semiconductor memory device of claim 4, wherein the shape of at least one of the blocking insulating layer and the tunnel insulating layer is an elliptically-shaped ring.

6. The semiconductor memory device of claim 5, wherein the channel separation structure and the insulating pillar are located inside the elliptically-shaped ring.

7. The semiconductor memory device of claim 1, further comprising:
a first blocking insulating segment located between the first data storage segment and the first concave portion of the gate stack;
a second blocking insulating segment located between the second data storage segment and the second concave portion of the gate stack;
a first tunnel insulating segment located between the first channel segment and the first data storage segment; and
a second tunnel insulating segment located between the second channel segment and the second data storage segment,
wherein the channel separation structure extends to a space between the first tunnel insulating segment and the second tunnel insulating segment and a space between the first blocking insulating segment and the second blocking insulating segment.

8. The semiconductor memory device of claim 1, wherein the gate stack includes a plurality of conductive layers spaced apart from each other and stacked along a direction, which is orthogonal to the straight line, and
each conductive layer comprises:
a first region surrounding a first outer portion of the first data storage segment;
a second region surrounding a second outer portion of the second data storage segment;
and a connection region connection the first region and the second region.

9. The semiconductor memory device of claim 1, wherein the channel separation structure includes a semiconductor oxide.

10. The semiconductor memory device of claim 1, further comprising:
a pillar separation structure extending between the first convex portion and the second convex portion of the insulating pillar so as to pass through the insulating pillar from the channel separation structure,
wherein the channel separation structure and the pillar separation structure are formed of an integrated insulating segment.

11. The semiconductor memory device of claim 1, further comprising:
a gate separation structure extending from the channel separation structure,
wherein the gate stack includes a first sub-stack and a second sub-stack separated by the channel separation structure and the gate separation structure.

12. The semiconductor memory device of claim 11, wherein the first sub-stack includes a plurality of first conductive layers spaced apart from each other and stacked in a direction, which is orthogonal to the straight line; and
wherein the second sub-stack includes a plurality of second conductive layers spaced apart from each other and stacked in the direction, which is orthogonal to the straight line.

13. The semiconductor memory device of claim 11, wherein the channel separation structure and the gate separation structure are formed of an insulating segment.

14. The semiconductor memory device of claim 13, wherein the insulating segment passes through the insulating pillar and extends between the first convex portion and the second convex portion of the insulating pillar.

15. The semiconductor memory device of claim 13, wherein the insulating segment and the insulating pillar are alternately located a direction, in which the straight line extends.

16. A semiconductor memory device comprising:
an insulating pillar having a first convex portion and a second convex portion, the first and second convex portions facing opposite directions based on a straight line on a geometric plane;
a gate separation structure located alternately with the insulating pillar in a direction, in which the straight line extends;
a first sub-stack including a first concave portion facing the first convex portion of the insulating pillar and further including a plurality of first conductive layers spaced apart from each other and stacked in a direction, which is orthogonal to the straight line;
a second sub-stack including a second concave portion facing the second convex portion of the insulating pillar and including a plurality of second conductive layers spaced apart from each other and stacked in the direction, which is orthogonal to the straight line;
a first data storage segment located between the first convex portion of the insulating pillar and the first concave portion of the first sub-stack;
a second data storage segment located between the second convex portion of the insulating pillar and the second concave portion of the second sub-stack; and
a channel layer located between the first data storage segment and the first convex portion of the insulating pillar and between the second data storage segment and the second convex portion of the insulating pillar,
wherein a width of each of the first data storage segment and the second data storage segment becomes narrower as each of the first date storage segment and the second data storage segment is close to the gate separation structure.

17. The semiconductor memory device of claim 16, wherein an elliptical hole extends through the first concave portion of the first sub-stack, the second concave portion of the second sub-stack, and the gate separation structure,
wherein the shape of the channel layer is an ellipse,
wherein a major axis of the elliptical-shape channel layer overlaps a minor axis of the elliptical hole, and
wherein a minor axis of the elliptical-shape channel layer overlaps the major axis of the elliptical hole.

18. The semiconductor memory device of claim 16, further comprising:
a tunnel insulating layer surrounding an outer portion of the channel layer; and
a blocking insulating layer located between the first data storage segment and the first concave portion of the first sub-stack, between the gate separation structure and the tunnel insulating layer, and between the second data storage segment and the second concave portion of the second sub-stack.

19. The semiconductor memory device of claim 18, wherein the blocking insulating layer forms a first elliptically-shaped ring,
the tunnel insulating layer forms a second elliptically-shaped ring,
a minor axis of the first elliptically-shaped ring overlaps a major axis of the second elliptically-shaped ring, and
a major axis of the first elliptically-shaped ring overlaps a minor axis of the second elliptically-shaped ring.

20. The semiconductor memory device of claim 19, wherein an outer convex portion of the first data storage segment faces the first sub-stack,
wherein an outer convex portion of the second data storage segment faces the second sub-stack, and
wherein the outer convex portions of the first and second data storage segments contact an inner concave portion of elliptically-shaped ring.

21. A method of manufacturing a semiconductor memory device, the method comprising:
forming a preliminary stack including a plurality of first material layers and a plurality of second material layers, the first and second material layers being alternately stacked;
forming a hole passing through the preliminary stack;
forming a data storage layer inside the hole, the data storage layer including an inner portion defining a first elliptical opening having a minor axis facing a first direction on a geometric plane and a major axis facing a second direction crossing the minor axis and an outer portion facing the preliminary stack;
isotropically etching the data storage layer through the first elliptical opening so that the first elliptical opening extends to a second elliptical opening having a major axis facing the first direction and a minor axis facing the second direction; and
forming a channel layer inside the second elliptical opening.

22. The method of claim 21, wherein the second elliptical opening is formed to separate the data storage layer into a first data storage segment and a second data storage segment, the first and second data storage segments spaced apart from each other in the second direction, and
wherein a width of each of the first data storage segment and the second data storage segment becomes narrower as each of the first data storage segment and the second data storage segment is close to the major axis of the second elliptical opening.

23. The method of claim 21, wherein the hole is formed in an elliptical shape having a minor axis facing the first direction and a major axis facing the second direction.

24. The method of claim 21, further comprising:
forming a blocking insulating layer along a side portion of the hole before forming the data storage layer;
forming a tunnel insulating layer along a side portion of the second elliptical opening before forming the channel layer; and
forming an insulating pillar inside the second elliptical opening after forming the channel layer.

25. The method of claim 24, further comprising:
opening a horizontal space between the plurality of first material layers by removing the plurality of second material layers;
forming a channel separation structure by selectively oxidizing a portion of the channel layer adjacent to the major axis of the second elliptical opening through the horizontal space; and
forming a third material layer inside the horizontal space.

26. The method of claim 24, forming a trench separating the channel layer into a first channel segment and a second channel segment by removing a portion of the insulating pillar and a portion of the channel layer overlapping the major axis of the second elliptical opening; and
forming an insulating segment inside the trench.

27. The method of claim 24, further comprising:
forming a trench extending in the first direction so as to overlap the major axis of the second elliptical opening and pass through a partial region of the insulating pillar, a partial region of the channel layer, and a partial region of the preliminary stack; and
forming an insulating segment inside the trench.

28. A method of manufacturing a semiconductor memory device, the method comprising:
forming a preliminary stack including a plurality of first material layers and a plurality of second material layers, the first and second material layers being alternately stacked;
forming a gate separation structure passing through the preliminary stack and extending in a first direction;
forming a hole passing through the gate separation structure and extending into the preliminary stack on both sides of the gate separation structure;
forming a data storage layer inside the hole, the data storage layer including an inner portion defining a first elliptical opening having a minor axis facing the first direction and a major axis facing a second direction crossing the minor axis and an outer portion facing the preliminary stack;
isotropically etching the data storage layer through the first elliptical opening so that the first elliptical opening extends to a second elliptical opening having a major axis facing the first direction and a minor axis facing the second direction; and
forming a channel layer inside the second elliptical opening.

29. The method of claim 28, wherein the data storage layer is divided into a first data storage segment and a second data storage segment adjacent in the second direction by the second elliptical openings, and
a width of each of the first data storage segment and the second data storage segment becomes narrower as each of the first data storage segment and the second data storage segment is close to the major axis of the second elliptical opening.

30. The method of claim 29, wherein the hole is formed in an elliptical shape having a minor axis facing the first direction and a major axis facing the second direction.

31. The method of claim 28, further comprising:
forming a blocking insulating layer along a side portion of the hole before forming the data storage layer;
forming a tunnel insulating layer along a side portion of the second elliptical opening before forming the channel layer; and
forming an insulating pillar inside the second elliptical opening after forming the channel layer.

32. The method of claim 31, further comprising:
removing the gate separation structure after forming the insulating pillar;
forming a recess portion exposing the insulating pillar by removing a portion of the blocking insulating layer, a portion of the tunnel insulating layer, and a portion of the channel layer through a region from which the gate separation structure is removed; and
forming an insulating segment inside the recess portion.

33. The method of claim 31, further comprising:
forming a recess portion exposing the gate separation structure by removing a portion of the insulating pillar and a portion of the tunnel insulating layer overlapping the major axis of the second elliptical opening, and a portion of the blocking insulating layer adjacent to the gate separation structure, after forming the insulating pillar; and
forming an insulating segment inside the recess portion.
